(19) United States
(12) Patent Application Publication
(10) Pub. No.: US 2005/0112292 A1
(43) Pub. Date: May 26, 2005

(54) Methods for treating at least one member of a microarray structure and methods of using the same

(76) Inventors: Russell Alan Parker, San Jose, CA (US); Duan M. Dutton, San Jose, CA (US); Nelson Robert Holcomb, Palo Alto, CA (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 10/722,950

(22) Filed: Nov. 25, 2003

(51) Int. Cl. C23C 16/00; B05D 3/04

(52) U.S. Cl. 427/508; 427/489; 427/255.37; 427/307; 427/534

(57) ABSTRACT

Methods for treating at least one member of a backing element/microarray assembly structure are provided. The subject methods include at least one of: (1) depositing a component on the at least one member, (2) extracting a component from the at least one member, and (3) surface modifying the at least one member, to treat the at least one member of a backing element/microarray assembly structure. Embodiments of the subject invention also include treated microarray structure members, e.g., produced in accordance with the subject methods, as well as methods for using treated microarray structure members in array assay protocols. Also provided are systems and kits for use in the subject methods.

### FIELD OF THE INVENTION

The field of this invention is microarrays.

### BACKGROUND OF THE INVENTION

Array assays between surface bound binding agents or probes and target molecules in solution may be used to detect the presence of particular analytes in the solution. The surface-bound probes may be nucleic acids (e.g., oligonucleotides, polynucleotides), peptides (e.g., polypeptides, proteins, antibodies) or other molecules capable of binding with target biomolecules in the solution (e.g., nucleic acids, proteins, etc.). Such binding interactions are the basis for many of the methods and devices used in a variety of different fields, e.g., genomics (in sequencing by hybridization, SNP detection, differential gene expression analysis, identification of novel genes, gene mapping, finger printing, etc.) and proteomics.

One typical array assay method involves biopolymeric probes immobilized in discrete locations on a surface of a substrate (collectively referred to herein as an “array”) such as a glass substrate or the like. A solution containing target molecules (“targets”) that bind with the attached probes is placed in contact with the bound probes under conditions sufficient to promote binding of targets in the solution to the complementary probes on the substrate to form a binding complex that is bound to the surface of the substrate. The pattern of binding by target molecules to probe features or spots on the substrate produces a pattern, i.e., a binding complex pattern, on the surface of the substrate, which pattern is then detected. This detection of binding complexes provides desired information about the target biomolecules in the solution.

The binding complexes may be detected by reading or scanning the array with, for example, optical means, although other methods may also be used, as appropriate for the particular assay. For example, laser light may be used to excite fluorescent labels attached to the targets, generating a signal only in those spots on the array that have a labeled target molecule bound to a probe molecule. This pattern may then be digitally scanned for computer analysis. Such patterns can be used to generate data for biological assays such as the identification of drug targets, single-nucleotide polymorphism mapping, monitoring samples from patients to track their response to treatment, assessing the efficacy of new treatments, etc.

In many instances, the microarray substrate is joined with a backing element substrate and a fluid retaining structure is positioned between the substrates to provide a microarray structure that forms a sealed array assay chamber in which an array assay protocol may be performed. Accordingly, such an array assay chamber includes the microarray substrate joined with the backing element substrate in such a manner that the fluid retaining structure is disposed therebetween to provide a volume defined by the walls of the fluid retaining structure and the surfaces of the array and backing element substrates. In this manner, the array assay chamber provides a barrier about the array for retaining fluid, e.g., a fluidic sample, in a fixed position relative to the array, i.e., to retain fluid in a position of contact with the array.

Regardless of the particular cause for adversely affecting an array assay, prior to the backing element's use in an array assay protocol, any such causes should be eliminated, e.g., deleterious substances should be removed or altered to minimize or eliminate their potential to adversely affect an array assay, surface chemistries altered, etc.

As such, there continues to be an interest in the development of new array based assay protocols in which the problems associated with adversely affected microarrays or their readings are minimized or eliminated. Of particular interest are backing element/microarray assembly structures that include microarray backing element substrates, microarray assemblies, and fluid retaining structure treatment processes that treat one or more members of a microarray structure to make the member(s) more suitable for use in array assays, such as treatment processes that alter the surface chemistry of microarray backing elements, e.g., modifying hydrophilic nature, minimize or eliminate leaching of material from fluid retaining structures, remove material from microarray backing elements that may adversely affect an array assay, etc.

References of Interest:

References of interest include: U.S. application Ser. No. 10/172,850.

### SUMMARY OF THE INVENTION

Methods for treating at least one member of a backing element/microarray assembly structure are provided. The subject methods include at least one of: (1) depositing a component on the at least one member, (2) extracting a component from the at least one member, and (3) surface modifying the at least one member, to treat the at least one member of a backing element/microarray assembly structure. Embodiments of the subject invention also include treated microarray structure members, e.g., produced in accordance with the subject methods, as well as methods for using treated microarray structure members in array assay protocols. Also provided are systems and kits for use in the subject methods.

### BRIEF DESCRIPTIONS OF THE DRAWINGS

FIG. 1 shows an exemplary embodiment of a microarray backing element that may be treated in accordance with the subject invention.

FIGS. 2A-2C show an exemplary embodiment of a microarray backing element treated according to the subject invention operatively positioned with respect to a microarray assembly to provide a backing element/microarray assembly structure that forms an array assay chamber about one or more arrays of the microarray assembly. Accordingly, FIG. 2A shows the exemplary treated backing element and microarray assembly prior to being operatively joined together to provide microarray structure and FIG. 2B shows the treated backing element and microarray operatively joined together to provide a backing element/microarray assembly structure that forms an array assay chamber. FIG. 2C shows a cross-sectional view of the structure of FIG. 2B.

### DEFINITIONS

The term “nucleic acid” as used herein means a polymer composed of nucleotides, e.g., deoxyribonucleotides or ribonucleotides, or compounds produced synthetically (e.g., PNA as described in U.S. Pat. No. 5,948,902 and the references cited therein) which can hybridize with naturally occurring nucleic acids in a sequence specific manner analogous to that of two naturally occurring nucleic acids, e.g., can participate in hybridization reactions, i.e., cooperative interactions through Pi electrons stacking and hydrogen bonds, such as Watson-Crick base pairing interactions, Wobble interactions, etc.

The terms “ribonucleic acid” and “RNA” as used herein mean a polymer composed of ribonucleotides.

The terms “deoxyribonucleic acid” and “DNA” as used herein mean a polymer composed of deoxyribonucleotides.

The term “oligonucleotide” as used herein denotes single stranded nucleotide multimers of from about 10 to about 100 nucleotides and up to about 200 nucleotides in length.

The term “polynucleotide” as used herein refers to single or double stranded polymer composed of nucleotide monomers of generally greater than about 100 nucleotides in length.

The term “monomer” as used herein refers to a chemical entity that can be covalently linked to one or more other such entities to form an oligomer. Examples of “monomers” include nucleotides, amino acids, saccharides, peptides, and the like.

The term “oligomer” is used herein to indicate a chemical entity that contains a plurality of monomers. As used herein, the terms “oligomer” and “polymer” are used interchangeably. Examples of oligomers and polymers include polydeoxyribonucleotides (DNA), polyribonucleotides (RNA), other polynucleotides which are C-glycosides of a purine or pyrimidine base, polypeptides (proteins), polysaccharides (starches, or polysugars), and other chemical entities that contain repeating units of like chemical structure.

The terms “nucleoside” and “nucleotide” are intended to include those moieties which contain not only the known purine and pyrimidine bases, but also other heterocyclic bases that have been modified. Such modifications include methylated purines or pyrimidines, acylated purines or pyrimidines, alkylated riboses or other heterocycles. In addition, the terms “nucleoside” and “nucleotide” include those moieties that contain not only conventional ribose and deoxyribose sugars, but other sugars as well. Modified nucleosides or nucleotides also include modifications on the sugar moiety, e.g., wherein one or more of the hydroxyl groups are replaced with halogen atoms or aliphatic groups, or are functionalized as ethers, amines, or the like.

“Optional” or “optionally” means that the subsequently described circumstance may or may not occur, so that the description includes instances where the circumstance occurs and instances where it does not.

The term “organic solvent” includes compounds that are liquid at room temperature and are not aqueous-based. These include not only carbon-based chemicals, but also highly fluorinated carbon based, carbon-silicon based, and silicon-only based chemistries, such as fluorocarbons and fluorosilicone compounds. The term also includes supercritical fluids, such as supercritical carbon dioxide.

An “array,” or “microarray” used herein interchangeably generally refers to an ordered array presented for binding to ligands such as polymers, polynucleotides, peptide nucleic acids and the like. Accordingly, arrays include any two-dimensional, as well as a three-dimensional, arrangement of addressable regions bearing a particular chemical moiety or moieties (e.g., biopolymers such as polynucleotide or oligonucleotide sequences (nucleic acids), polypeptides (e.g., proteins), carbohydrates, lipids, etc.) associated with that region. In the broadest sense, the arrays are arrays of polymeric binding agents, where the polymeric binding agents may be any of: polypeptides, proteins, nucleic acids, polysaccharides, synthetic mimetics of such biopolymeric binding agents, etc. In many embodiments of interest, the arrays are arrays of nucleic acids, including oligonucleotides, polynucleotides, cDNAs, mRNAs, synthetic mimetics thereof, and the like. Where the arrays are arrays of nucleic acids, the nucleic acids may be covalently attached to the arrays at any point along the nucleic acid chain, but are generally attached at one of their termini (e.g. the 3′ or 5′ terminus). Sometimes, the arrays are arrays of polypeptides, e.g., proteins or fragments thereof.

Any given microarray substrate may carry one, two, four or more or more arrays disposed on a front surface of a substrate. Depending upon the use, any or all of the arrays may be the same or different from one another and each may contain multiple spots or features. A typical array may contain from about one to about ten or more, e.g., more than ten, more than one hundred, more than one thousand, more than ten thousand features, or even more than one hundred thousand features, in an area of less than 20 cm² or even less than 10 cm². For example, features may have widths (that is, diameter, for a round spot) in the range from a 10 μm to 1.0 cm. In other embodiments each feature may have a width in the range of 1.0 μm to 1.0 mm, usually 5.0 μm to 500 μm, and more usually 10 μm to 200 μm. Non-round features may have area ranges equivalent to that of circular features with the foregoing width (diameter) ranges. At least some, or all, of the features are of different compositions (for example, when any repeats of each feature composition are excluded the remaining features may account for at least 5%, 10%, or 20% of the total number of features). Interfeature areas will typically (but not essentially) be present which do not carry any polynucleotide (or other biopolymer or chemical moiety of a type of which the features are composed). Such interfeature areas typically will be present where the arrays are formed by processes involving drop deposition of reagents but may not be present when, for example, photolithographic array fabrication processes are used. It will be appreciated though, that the interfeature areas, when present, could be of various sizes and configurations.

Each array may cover an area of less than 100 cm², or even less than 50 cm², 10 cm² or 1 cm². In many embodiments, the substrate carrying the one or more arrays will be shaped generally as a rectangular solid (although other shapes are possible), having a length that may range from about 4 mm to about 1 m, usually more than about 4 mm to about 600 mm, more usually less than about 400 mm; a width that may range from about 4 mm to about 1 m, usually less than about 500 mm and more usually less than about 400 mm; and a thickness that may range from about 0.01 mm to about 5.0 mm, usually from about 0.1 mm to about 2 mm and more usually from about 0.2 to about 1.5 mm.

An array is “addressable” when it has multiple regions of different moieties (e.g., different polynucleotide sequences) such that a region (i.e., a “feature” or “spot” of the array) at a particular predetermined location (i.e., an “address”) on the array will detect a particular target or class of targets (although a feature may incidentally detect non-targets of that feature). Array features are typically, but need not be, separated by intervening spaces. In the case of an array, the “target” will be referenced as a moiety in a mobile phase (e.g., an aqueous fluid), to be detected by probes (“target probes”) which are bound to the substrate at the various regions. However, either of the “target” or “target probe” may be the one that is to be evaluated by the other (thus, either one could be an unknown mixture of polynucleotides or proteins to be evaluated by binding with the other). A “scan region” refers to a contiguous (preferably, rectangular) area in which the array spots or features of interest, as defined above, are found. The scan region is that portion of the total area illuminated from which the resulting fluorescence is detected and recorded. An “array layout” refers to one or more characteristics of the features, such as feature positioning on the substrate, one or more feature dimensions, and an indication of a moiety at a given location. “Hybridizing” and “binding”, with respect to polynucleotides and proteins, are used interchangeably.

“Microarray assembly” refers to an array substrate having one or more arrays thereon.

“Microarray structure” or “backing element/microarray assembly structure” used herein interchangeably to refer to a structure that at least includes (1) a backing element substrate, (2) a gasket, and (3) a microarray assembly, operatively joined together wherein a gasket is positioned between the backing element substrate and microarray substrate about at least one microarray of the microarray assembly to provide a sealed microarray chamber about at least one array of the microarray assembly. The gasket may be fixedly or securely attached (e.g., using adhesives, form in place processes, etc.) to the backing element substrate or the microarray substrate such that it is not readily removable therefrom or the gasket may be a separate component.

“Remote location,” means a location other than the location at which the array is present and hybridization occurs. For example, a remote location could be another location (e.g., office, lab, etc.) in the same city, another location in a different city, another location in a different state, another location in a different country, etc. As such, when one item is indicated as being “remote” from another, what is meant is that the two items are at least in different rooms or different buildings, and may be at least one mile, ten miles, or at least one hundred miles apart.

The term “sample” as used herein relates to a material or mixture of materials, typically, although not necessarily, in fluid form, containing one or more components of interest.

The term “ligand” as used herein refers to a moiety that is capable of covalently or otherwise chemically binding a compound of interest. Ligands may be naturally-occurring or manmade. Examples of ligands include, but are not restricted to, agonists and antagonists for cell membrane receptors, toxins and venoms, viral epitopes, hormones, opiates, steroids, peptides, enzyme substrates, cofactors, drugs, lectins, sugars, oligonucleotides, nucleic acids, oligosaccharides, and proteins.

The term “receptor” as used herein is a moiety that has an affinity for a ligand. Receptors may be naturally-occurring or manmade. They may be employed in their unaltered state or as aggregates with other species. Receptors may be attached, covalently or noncovalently, to a binding member, either directly or via a specific binding substance. Examples of receptors include, but are not restricted to, antibodies, cell membrane receptors, monoclonal antibodies and antisera reactive with specific antigenic determinants, viruses, cells, drugs, polynucleotides, nucleic acids, peptides, cofactors, lectins, sugars, polysaccharides, cellular membranes, and organelles. Receptors are sometimes referred to in the art as anti-ligands. As the term receptors is used herein, no difference in meaning is intended. A “Ligand Receptor Pair” is formed when two molecules have combined through molecular recognition to form a complex.

The term “surfactant” is used herein in its conventional sense to refer to a compound that effects reduction in the surface tension in a fluid and promotes the wetting of surfaces by the fluid. Examples of surfactants include anionic, cationic, amphoteric and nonionic surfactants.

“Surface energy” is as defined in U.S. Pat. No. 6,444,268, the disclosure of which is herein incorporated by reference.

The term “contact angle” is as defined in U.S. Pat. No. 6,458,526, the disclosure of which is herein incorporated by reference.

The term “array assay solution” or “array assay reagent” used herein interchangeably refers to a solution suitable for use in an array assay and include, where the array assay is a hybridization assay, the terms “hybridization solution” and “hybridization reagent” used herein interchangeably to refer to a solution suitable for use in a hybridization reaction.

### DETAILED DESCRIPTION OF THE INVENTION

Methods for treating at least one member of a backing element/microarray assembly structure are provided. The subject methods include at least one of: (1) depositing a component on the at least one member, (2) extracting a component from the at least one member, and (3) surface modifying the at least one member, to treat the at least one member of a backing element/microarray assembly structure. Embodiments of the subject invention also include treated microarray structure members, e.g., produced in accordance with the subject methods, as well as methods for using treated microarray structure members in array assay protocols. Also provided are systems and kits for use in the subject methods.

Before the present invention is described, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range is encompassed within the invention. The upper and lower limits of these smaller ranges may independently be included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, the preferred methods and materials are now described. All publications mentioned herein are incorporated herein by reference to disclose and describe the methods and/or materials in connection with which the publications are cited.

It must be noted that as used herein and in the appended claims, the singular forms “a”, “an”, and “the” include plural referents unless the context clearly dictates otherwise.

The publications discussed herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention.

The figures shown herein are not necessarily drawn to scale, with some components and features being exaggerated for clarity.

As summarized above, the subject invention provides methods for treating at least one member of a backing element/microarray assembly structure. In further describing the subject invention, the subject microarray backing element treatment methods are reviewed first, followed by a review of methods in which treated backing element/microarray assembly structures may find use.

Methods for Treating at Least One Member of a Microarray Backing Element/Microarray Assembly Structure

As summarized above, the subject invention includes methods for treating at least one member of a backing element/microarray assembly structure (“microarray structure”). More specifically, the subject invention provides methods for treating at least one member (i.e., at least one of: a microarray backing element substrate, gasket structure, microarray assembly (e.g., a microarray substrate)) of a backing element/microarray assembly structure by depositing at least one component on the structure member, extracting at least one component from the structure member, modifying a surface of the structure member, and combinations thereof. For example, embodiments of the subject invention include using one or more treatment agents such as plasma and a solvent, e.g., an aqueous solvent or organic solvent, to treat treating at least one member of a backing element/microarray assembly structure. Accordingly, such embodiments include the contact of at least part of a microarray backing element substrate, gasket structure, microarray assembly (e.g., a microarray substrate) with plasma, a solvent or in certain embodiments both plasma and a solvent, e.g., in sequential order, to treat the microarray structure member.

As summarized above, the subject methods are employed to treat at least one of a microarray backing element, gasket structure, microarray assembly (e.g., a microarray substrate. The term “microarray backing element” is meant broadly to refer to any suitable element that may be operatively mated or joined with a microarray assembly, with a gasket structure positioned therebetween, to provide an array assay chamber about an array of the microarray assembly. Accordingly, when operatively joined together such that a microarray assembly is in place on a backing element (or vice versa), a backing element/microarray assembly structure is provided and forms a tightly sealed array assay chamber is provided. Such backing elements typically at least include a backing element substrate or solid support. Backing elements may also include at least one fluid retaining structure (also referred to herein as a fluid containment structure and gasket) and more specifically may include a solid support having a surface bounded by at least one fluid retaining structure. The fluid retaining structure may be fixedly attached to a backing element substrate, a microarray substrate, or may be a separable component. As described herein, a fluid retaining structure is primarily described as associated with a backing element substrate for convenience, but where such description is in no way intended to limit the scope of the invention. With a microarray assembly in place (in close proximity (“adjacent”) to the backing element), the backing element, microarray and gasket structure define a backing element/microarray assembly structure that forms an array assay chamber. In other words, the backing element is dimensioned to fit with an array, with a fluid retaining structure positioned therebetween, to produce a reaction volume bounded on the top and bottom by the microarray substrate surface and backing element substrate surface and on the sides by the walls of the fluid retaining structure such that the microarray fabricated as described above is contained within the area bounded by the fluid retaining structure. Representative backing elements that may be treated in accordance with the subject invention are reviewed in greater detail below.

The term “treat” is broadly meant any desired action or result that may alter, change, transform, enhance or otherwise effect at least one member of a backing element/microarray assembly structure, e.g., a microarray backing element (i.e., the substrate surface and/or a surface of a fluid retaining structure including a surface within a fluid retaining structure) of the microarray backing element. Embodiments include treating at least one member of a microarray structure, e.g., a microarray backing element substrate, gasket, array substrate, by subjecting at least a portion of a member of a microarray structure member, e.g., a microarray backing element substrate and the like, to a deposition and/or extraction and/or surface modification protocol, e.g., to deposit at least one component such as a thin film or layer on at least a portion of at least one member of the microarray structure member and/or extracting at least one component from at least a portion of the member and/or surface modifying at least a portion of a member of a microarray structure. Such treatments may include, but are not limited to, cleaning, including removing or extracting unwanted substances or substances that may be deleterious to, or adversely affect, an array or its reading, surface modifications such as providing functional groups, changing wettability (i.e., increasing such as enhancing or decreasing hydrophilicity), deposition of material such as coatings, films, layers, etc. For example, a problem that may be encountered with array assay chambers formed by a microarray substrate, gasket and a microarray backing element is that deleterious substances or contaminants of the backing element substrate and/or gasket may adversely affect an array assay performed within the array assay chamber, e.g., adversely affect an array or its reading. A variety of substances associated with a backing element and/or gasket may adversely affect array assay results, e.g., substances may remain on the backing element substrate and/or on a gasket from previous manufacturing processes, may be a result of a particular material used to fabricate the given member, etc. For example, substances that may adversely impact data that is obtained from an array assay may include moieties that leach from the gasket over time. For example, in certain embodiments the material of a gasket may be somewhat fluorescent and thus any leached material related to this material of the gasket may also be fluorescent. If the array assay is one that employs fluorescent techniques to read the array, this leached material may be read along with the array and may be misinterpreted to be malformed DNA features and/or the material may interfere with the binding of the specific binding members and/or produce areas of high background, etc. Accordingly, embodiments of the treatment protocols of the subject invention include removing these undesirable or unwanted moieties from at least one member of a microarray backing element/gasket/array structure (e.g., from a gasket or substrate to which a gasket is associated) that may leach from the gasket and adversely affect an array or its reading. Treatment protocols may be readily adapted from known protocols, by one of skill in the art, without undue experimentation. For example, exemplary treatments and protocols for practicing the same that may be adapted for use in the subject invention include, but are not limited to, those described in Plasma Surface Modification of Polymers: Relevance to Adhesion, M. Strobel, C. S. Lyons, and K. L. Mittal, eds., 1994; Plasma Surface Modification of Polymers: Relevance to Adhesion, Vol. 2, K. L. Mittal, ed., 2000; Physical Chemistry of Surfaces, Vol. 6, Arthur W. Adamson and Alice P. Gast, 1997; and the like.

Furthermore, in certain instances an array assay may be adversely affected by the inherent properties (e.g., the surface chemistry) of the backing element. For example, oftentimes in the performance of an array assay protocol using a backing element to provide an array assay chamber, mixing or movement of a sample retained in the array assay chamber may be accomplished by moving or agitating a bubble around the sample contained by a fluid retaining structure present on a backing element substrate, e.g., by rotational mixing. However, in many instances the fluid retaining structure is hydrophobic such as in the case of fluid retaining structures that are elastomers. The contact of the bubble with the hydrophobic fluid retaining structure of the backing element during rotational mixing may cause a plurality of bubbles of air to form from, or rather break away from, a single mixing bubble. Too many bubbles may impede the mixing process and may reach point where mixing is stopped all together. Accordingly, in such instances the inventors of the subject invention have realized that a treatment of the backing element that addresses inherent properties of the backing element that may adversely impact array assay results, e.g., a modification that increases hydrophilicity of certain backing element surfaces—including fluid retaining structure surfaces, would eliminate or minimize the adverse impact upon the array assay results. Accordingly, treatment protocol embodiments of the subject invention include changing the dewetting characteristics of at least one member of a backing element/microarray assembly structure, e.g., increasing hydrophilicity as measured by receding contact angle, etc.

Other problems that may be encountered with the use of a backing element include the unintentional deposition of a hydrophobic material such as a hydrophobic fluid on the substrate surface during manufacture of the backing element. In this regard, embodiments of the treatment protocols of the subject invention include the removal of unintentionally deposited hydrophobic material such as hydrophobic fluids from a backing element regardless of the source, e.g., oils, plasticizers, or other hydrophobic materials released or used in the manufacturing process.

Accordingly, in practicing embodiments of the subject methods, a deposition protocol and/or extraction protocol and/or surface modification protocol is performed on a microarray backing element. By “deposition” is used herein broadly to refer to the addition of material to the surface of at least one member of a backing element/microarray assembly structure, e.g., the backing element substrate and/or fluid retaining structure. By “extraction” is used herein broadly to refer to the removal of undesired or unwanted moieties from the surface and/or interior of at least one member of a backing element/microarray assembly structure, e.g., the backing element substrate and/or fluid retaining structure. These moieties may be any moieties that are desired to be removed from a member of a backing element/microarray assembly structure for any reason, e.g., they may adversely affect array assay results (e.g., adversely affect an array or its reading). By “surface modification” is used herein broadly to refer to changing the physical and/or chemical properties of the surface of at least one member of a backing element/microarray assembly structure, e.g., the backing element substarte and/or fluid retaining structure. As described in greater detail below, embodiments include contacting at least a portion of at least one member of a backing element/microarray assembly structure, e.g., a microarray backing element substrate with at least one backing element treatment agent or the like, where such treatment agents include, but are not limited to, metals; SiO₂, solvents, e.g., aqueous and organic solvents; vapors; plasmas; gas/air mixes, e.g., flame treatments; beads, e.g., bead blasting; radiant energy, e.g., exposure to ultraviolet light with oxygen (UV/O₂); electrons, e.g., electron bombardment; reactive gases; and solubalizing agents, e.g., for solubalizing soluble particles present in or on a backing element. In treating at least one member of a backing element/microarray assembly structure according to the subject invention, the entire member be treated, or only a portion of the member may be treated. Embodiments also include treating a first area of a microarray backing element with a first treatment and/or treating a second area with a second treatment, where portions of the first and second areas may or may not overlap. In any event, at least the area(s) of at least one member of a backing element/microarray assembly structure that is to be treated is completely treated to provide desired results, e.g., completely contacted with plasma and/or solvent under conditions sufficient to treat the intended area(s) of the structure member.

As noted above, a backing element is one member of a backing element/microarray assembly structure Accordingly, embodiments of the subject invention may be employed to treat a wide variety of microarray backing elements. Of interest is the treatment of a microarray backing element which includes a fluid retaining structure that is a polymeric fluid retaining structure, e.g., an elastomeric fluid retaining structure. The fluid retaining structure may be fixedly or readily removable from the backing element substrate. Accordingly, microarray backing elements that may be treated in accordance with the subject invention may include a solid substrate with a surface bounded by a polymeric fluid retaining structure, e.g., an elastomeric fluid retaining structure, as will be described in greater detail below, where such may be fixedly attached or seperable. However, while the subject invention is primarily described with reference to microarray backing elements that include a polymeric fluid retaining structure, e.g., an elastomeric fluid retaining structure, it is to be understood that the subject invention is not limited to these types of microarray backing elements. Before further describing the subject methods, a review of representative embodiments of microarray backing elements is first provided.

Representative Microarray Backing Elements

Microarray backing elements that may be treated according to the subject methods may include a solid substrate having at least one substrate surface. As noted above, upon such as surface may be fixedly or separably positioned at least one fluid retaining structure, where in certain embodiments a plurality of fluid retaining structures may be present on the substrate surface such that a plurality of fluids such as samples may be retained in each of the fluid retaining structures without cross-contamination of the fluids. In accordance with the subject invention, each subject fluid retaining structure is configured to hold and effectively retain a volume of fluid such as a volume of a fluidic sample, e.g., for use in an array assay protocol such as an analyte detection protocol. Representative microarray backing elements are disclosed, e.g., in U.S. application Ser. No. 10/172,850; the disclosure of which is herein incorporated by reference.

As note above, the microarray backing elements treated in accordance with the subject invention generally include a solid substrate. The substrates may assume a variety of shapes and sizes, where they are typically configured (e.g., sized, shaped, etc.) to be operatively associated or joined with another substrate (i.e., a microarray substrate) having at least one array thereon to provide an array assay chamber, as will be described in greater detail below. At least one surface of a backing element surface is usually planar, but in certain embodiments may deviate from planar, e.g., portions of the substrate surface may be non-planar (e.g., may include recessed structures, elevated structures, channels, orifices, guides, and the like).

Typically, the particular shape of a subject substrate is dictated at least in part by the microarray substrate with which it may be used such that the shape of the substrate is one which corresponds or “fits” with a microarray substrate. The shape of these backing element substrates ranges from simple to complex. In many embodiments, the substrates may assume a square, rectangular, oblong, oval or circular shape, etc., as well as other geometric shapes and irregular or complex shapes.

Likewise, the size of the subject backing element substrates may vary depending on a variety of factors, including, but not limited to, the number of fluid retaining structures present thereon, the particular microarray substrate to which it is to be joined, etc. Generally, the subject backing element substrates are sized to be easily transportable or moveable. For example, the backing element substrate may be shaped generally as a rectangle (although other shapes are possible, e.g., circular, etc.), having a length that may range from about 4 mm to about 1 m, usually more than about 4 mm to about 600 mm, more usually less than about 400 mm, e.g., the length may range from about 25 mm to about 150 mm, e.g., from about 50 mm to about 100 mm, e.g., from about 65 mm to about 80 mm; a width that may range from about 4 mm to about 1 m, usually less than about 500 mm and more usually less than about 400 mm, e.g., the width may range from about 15 mm to about 40 mm, e.g., from about 20 mm to about 35 mm, e.g., from about 20 mm to about 30 mm; and a thickness that may range from about 0.01 mm to about 5.0 mm, e.g., from about 0.02 to about 2 mm, e.g., 0.1 to about 1.5 mm, e.g., about 0.5 mm to about 1.5 mm. Shapes other than rectangular may have analogous dimensions.

Substrate materials are chosen to provide sufficient physical support for one or more fluid retaining structures positioned on at least one surface of the backing element substrate and are also chosen to endure the conditions of any treatment or handling or processing that may be encountered in the use of the substrate, array assays, e.g., hybridization assays, protein binding assays, etc. One or more materials may be used to fabricate the backing element substrates such that a plurality of materials may be employed. Examples of materials which may be used to fabricate the subject substrates include, but are not limited to, metals such as stainless steel, aluminum, and alloys thereof; polymers, e.g., plastics and other polymeric materials such as poly (vinylidene fluoride), poly(ethyleneterephthalate), polyurethane, e.g., nonporous polyurethane, fluoropolymers such as polytetrafluoroethylene (e.g., Teflon®), polypropylene, polystyrene, polycarbonate, PVC, nylon, and blends thereof; siliceous materials, e.g., glasses, fused silica, ceramics and the like.

The backing element substrates may also be fabricated from a “composite,” i.e., a composition made up of different or unlike materials. The composite may be a block composite, e.g., an A-B-A block composite, an A-B-C block composite, or the like. Alternatively, the composite may be a heterogeneous combination of materials, i.e., in which the materials are distinct from separate phases, or a homogeneous combination of unlike materials. As used herein, the term “composite” is used to include a “laminate” composite. A “laminate” refers to a composite material formed from several different bonded layers of identical or different materials.

As described above, embodiments of the backing element substrates may include at least one fluid retaining structure (i.e., gasket) present on at least one surface of the substrate. In certain embodiments the one or more fluid retaining structures present on a substrate surface includes a material that changes from a first fluid state to a second solid state in response to a stimulus and include Form in Place Gaskets such as described in U.S. patent application Ser. No. 10/010,945. In many embodiments, multiple, discrete fluid retaining structures may be present on a backing element substrate surface so that multiple samples, which may be the same or different, to be applied to a single backing element substrate (i.e., to each fluid retaining structure), without cross-contamination of the samples.

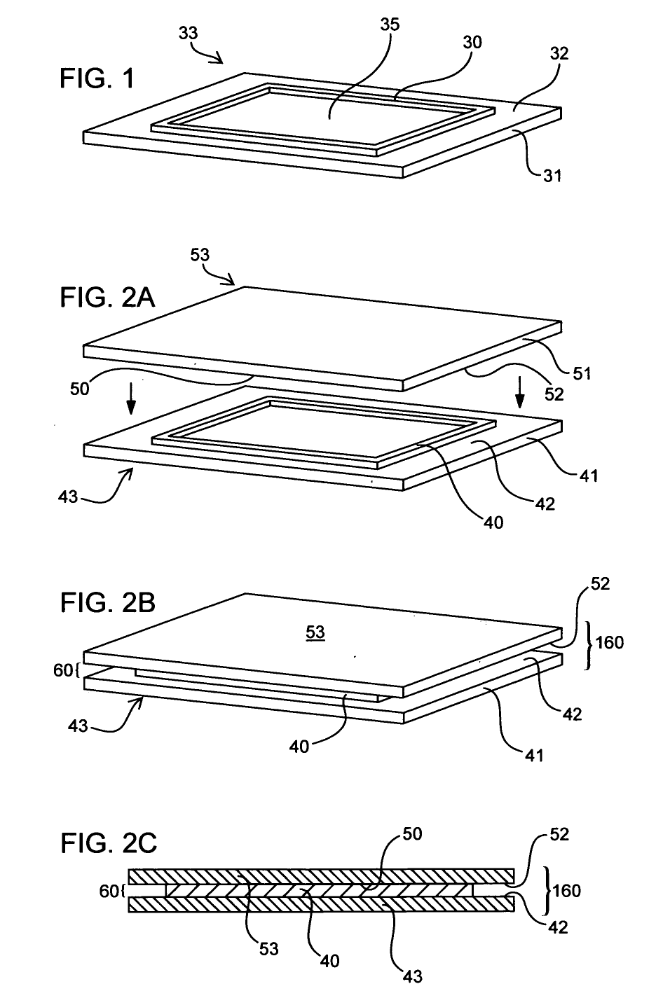

FIG. 1 shows an exemplary embodiment of a microarray backing element that may be treated in accordance with the subject invention. As shown, a microarray backing element 33 includes fluid retaining structure 30 which is disposed around and marks the perimeter of an interior area 35 on surface 32 of a backing element substrate 31. The interior area and the fluid retaining structure thus define a well structure that is adapted for retaining a fluid, where the well is defined by the walls of the fluid retaining structure and the backing element substrate surface that is bounded or enclosed by the fluid retaining structure (i.e., the interior area). The shape of the interior area may be altered depending on the desired use, e.g., by altering the configuration of the fluid retaining structures and/or substrate surface, and the like.

The shape of a fluid retaining structure will depend on a variety of factors such as the particular array feature or spot it is intended to encompass. As such, the subject fluid retaining structures may assume a variety of different shapes such that the shapes of these structures range from simple to complex. In many embodiments, the fluid retaining structures will assume a square, rectangular, oblong, oval or circular shape, although other shapes are possible as well, such as other geometric shapes, as well as irregular or complex shapes. In certain embodiments, the width or diameter of a fluid retaining structure may not be constant throughout the entire thickness or height of the structure, i.e., the width may vary. Accordingly, shapes such as cone-like, spiral, helical, pyramidal, parabolic or frustum are possible as well.

Typically, the number of fluid retaining structures present on a backing element substrate may range from about 1 to about 20 or more, for example as many as about 25 or more fluid retaining structures may be present on a single substrate. As such, the configuration or pattern of fluid retaining structures may vary depending on the particular array assay to be performed, the number of fluid retaining structures present, the size and shape of the fluid retaining structures present, the size, shape and pattern of the arrays to which the fluid retaining structures are to be joined, etc. For example, the pattern of the fluid retaining structures may be in the form of a grid or other analogous geometric or linear pattern or the like, e.g., analogous to a conventional microtiter plate grid pattern and in certain embodiments the fluid retaining structures are present in a non grid-like or non-geometric pattern.

The physical dimensions of a subject fluid retaining structure may be characterized in terms of thickness, and/or width, and/or length (e.g., length may be used for structures having non-round shapes). Thickness or height is defined as the perpendicular distance from the substrate surface to most distal (i.e., top) surface of the fluid retaining structure. The width of a fluid retaining structure is defined as the distance from one side of a fluid retaining structure through the fluid retaining structure to the opposing side of the fluid retaining structure, proceeding on a line parallel to the fluid retaining structure surface, but perpendicular to the fluid retaining structure's long axis at the particular point where the length is being measured. The length is defined as the long axis of the fluid retaining structure that is parallel to the plane of the substrate surface. In structures having round or round-like (e.g., oblong, etc.) shapes, the length may be analogous to a major axis. In those embodiments having more than one fluid retaining structure, it is to be understood that the dimensions (and/or the shapes and/or materials) of the fluid retaining structures may be the same or some or all of the fluid retaining structures may have different dimensions (and/or shapes and/or materials).

In general, the dimensions of a fluid retaining structure are such that any fluid retaining structure is able to accommodate a volume of fluid sufficient to perform an array assay, i.e., able to retain a sufficient volume of sample for an array assay. Typically, the fluid retaining structures or rather the wells formed thereby (defined by the surface of the substrate on which it is positioned and the fluid barrier walls), confine a liquid volume of at least about 1-5 μl, where the volume may range from about 1 μl to about 1000 μl, usually from about 10 μl to about 1000 μl, where the volume may be as great as about 1000 μl to about 5000 μl or greater.

The thickness or height of a fluid retaining structure is of a dimension that is suitable to retain a sufficient amount of sample for an array assay. Accordingly, a fluid retaining structure may have a height or thickness of at least about 5 to about 10 micrometers, e.g., at least about 15 micrometers in certain embodiments, e.g., at least about 20 micrometers in certain embodiments, where in certain embodiments the height may be about 25 micrometers to about 100 micrometers or more or even up to about 250 micrometers or more, where the height may be up to about 500 micrometers or more, even up to about 1000 micrometers or up to about 5000 micrometers or more, where the height may be a few millimeters or more in certain embodiments. The length may be at least about 20 to about 50 micrometers, e.g., may be at least about 150 micrometers or more, e.g., may be at least about 150 micrometers to about 250 micrometers or more, where in certain embodiments the width may be up to about 300 micrometers or more, e.g., up to about 400 micrometers or more or even up to about 500 micrometers or more in certain embodiments, even up to about 700 micrometers or even up to about 1000 micrometers or more in some embodiments. The width may range up to about 1.5 mm, sometimes up to about 3 mm, and sometimes up to about 6 mm in certain embodiments. The width of a fluid retaining structure, defined by the distance from one side of a fluid retaining structure through the wall to the opposing side of the fluid retaining structure, may vary, where the width may be at least about 20 to about 50 micrometers, e.g., may be at least about 150 micrometers or more, e.g., may be at least about 150 micrometers to about 250 micrometers or more, where in certain embodiments the width may be up to about 300 micrometers or more, e.g., up to about 400 micrometers or more or even up to about 500 micrometers or more in certain embodiments, even up to about 700 micrometers or even up to about 1000 micrometers or more in some embodiments. For example, the width may range up to about 1.5 mm, sometimes up to about 3 mm, and sometimes up to about 6 mm in certain embodiments.

The fluid retaining structure material(s) is selected to provide a fluid retaining structure having particular properties, e.g., suitable thickness, structure and fluid retaining properties, stability, inertness, array assay protocol compatibility, etc. The subject fluid retaining structures may be flexible or deformable upon application of a suitable force thereto or may be rigid, i.e., not easily deformable or not deformable at all upon application of a suitable force thereto.

The fluid retaining structure may be made of any suitable material. In certain embodiments as noted above, a fluid retaining structure includes a material that changes from a first fluid state to a second solid state in response to a stimulus. In other words, in certain embodiments the fluid retaining structure may be formed by employing a suitable curing protocol and as such the material of the fluid retaining structures may correctly be characterized as a curable material in certain embodiments. In other words, in such embodiments the material of the fluid retaining structures may be transformed or otherwise altered or changed from a fluid state to a second, solid or semi-solid state in response to a stimulus, where the transformation, alteration or change from the fluid state to the solid state is irreversible.

In those embodiments where the fluid retaining structure(s) are formed from a material that changes from a first fluid state to a second solid state, the solid state or solid form of the fluid retaining structure is suitable for retaining a fluid within its boundaries and suitable for use in an array protocol. The subject fluid retaining structures may be changed from a first fluid state to a second solid state prior to or after being positioned at an intended location on a backing element substrate surface such that in certain embodiments the fluid retaining structure is formed (i.e., changed from a first fluid state to a second solid state) “in place” on a microarray backing element substrate and in certain other embodiments the fluid retaining structure is formed at a first location which is a location other than on a surface of a backing element substrate upon which it will ultimately be positioned and then transferred to a backing element substrate.

Suitable fluid retaining structure materials may derive from naturally occurring materials, naturally occurring materials that have been synthetically modified, or synthetic materials. Fluid retaining structures materials may be made of fluid materials that may be cured to provide a solid fluid retaining structure having suitable characteristics. Selection of a fluid retaining structure material is determined relative to the intended application. Suitable fluid retaining structure materials include, but are not limited to polymers such as polypropylenes, urethanes including polyurethanes, acrylates, elastomers, silicone sealants (e.g., Loctite 5964 thermal cure silicone), polysulfides, latex, acrylic, etc. In certain embodiments, the fluid retaining structure material is a fluoropolymer such as polytetrafluoroethylene, e.g., a Teflon® such as a liquid Teflon®, e.g., Teflon® AF which are a family of amorphous fluoropolymers provided by E.I. du Pont de Nemours and Company. In certain embodiments, the fluid retaining structure includes a polymer that is an elastomer (e.g., polyisoprene, polybutadiene, polyisobutylene, polyurethanes, and the like).

In those embodiments where the fluid retaining structure(s) are formed from a material that changes from a first fluid state to a second solid state, after the fluid retaining structure material is deposited in a fluid form in the predetermined configuration either at the desired site on a backing element substrate surface or at another location (e.g., a non-backing element substrate), the fluid retaining structure material is changed or transformed or rather is cured to form a fluid retaining structure that is solid by the application of a suitable stimulus thereto. Any suitable stimulus may be employed, where various stimuli are known in the art for changing a fluid material to a solid material. Accordingly, various methods of curing are available and may be utilized with the subject invention, the choice of which depends on a variety of factors such as the particular fluid retaining structure material(s) used, i.e., the particular properties of the material(s), the amount of time available for curing, etc.

For example, in certain embodiments, a fluid retaining structure material may be exposed to moisture to cause or to speed up the curing process. In such embodiments, moisture in the air reacts with the material to cure it. For example, moisture cure RTV silicone may be employed. Typical cure times for these RTV silicones range from about 1 day to about several days. In certain embodiments, the fluid retaining structure material may be exposed to heat to cause or to speed up the curing process. Heat cure fluid retaining structure material, such as heat cure silicone, is cured by a process of heating the material well above room temperature for a sufficient period of time, typically from about 10 minutes to about 2 hours. In certain embodiments, the fluid retaining structure material may be exposed to UV or visible light to cause or to speed up the curing process. Curing by UV cure is usually relatively fast, e.g., curing times from as little as about a few seconds, for example ranging from as little as 1 second to about 30 seconds or so. In certain embodiments, curing agents may be employed that cause or facilitate the curing process. These curing agents are typically catalysts to the curing process and may be used with one or more polymers, e.g., a polymer/catalyst combination may be employed. In certain embodiments, two or more curing protocols are employed.

Treating at Least One Member of a Microarray Backing Element/Microarray Assembly Structure

The subject invention includes treating at least one member of a backing element/microarray assembly structure used in an array assay. Such structure member may be at least one of: a backing element substrate, an array assembly (e.g., an array substrate) and a fluid retaining structure (which may be associated with the backing element substrate, microarray substrate or may be a separate element). Accordingly, embodiments for practicing the subject methods to treat at least one of: a backing element substrate, an array substrate and a fluid retaining structure (which may be associated with the backing element substrate, microarray substrate or may be a separate element) is subjected to at least one treatment process. A variety of different treatment protocols may be performed on at least one of: a backing element substrate, an array substrate and a fluid retaining structure to treat the particular array component(s), where the particular treatment process performed will depend, e.g., on the particular materials of the array component(s) being treated, e.g., the particular backing element, the particular manufacturing processes of the array component being treated, and the like. Treatment processes usually include contacting at least one array component with at least one treatment agent under conditions sufficient to treat the array component(s). As described in greater detail below, treatment agents include, but are not limited to, plasmas and solvents including aqueous solvent, organic solvents and super critical fluidic solvents (e.g., super critical CO₂ and the like), electromagnetic radiant energy, e.g., UV/O₃, and the like. Exemplary treatments of backing elements that include a backing element substrate having at least one fluid retaining structure present on a surface thereof is used to further describe the subject invention. It is to be understood that such is for exemplary purposes only and in no way intended to limit the subject invention as any member of a backing element/microarray assembly structure (microarray assembly (e.g., microarray assembly), backing element substrate, fluid retaining element substrate-whether fixedly attached to a microarray substrate or backing element substrate or not) may be treated in accordance with the subject invention. In those embodiments wherein a microarray substrate is treated, such is usually performed prior to fabricating an array on a surface of the substrate. It is to be understood that when referring to treating a backing element substrate, an analogous treatment may be performed on a microarray substrate or any other array structure member. When referring to treating a gasket structure, an analogous treatment may be performed on any other array structure member and it is further to be understood that a treated gasket may be fixedly associated with a backing element substrate, fixedly associated with a microarray substrate or may be a separate element from both. As such, a gasket may be treated while fixedly attached to a substrate.

Any portion or all of the particular member of a backing element/microarray assembly structure, e.g., backing element, may be treated. For example, in those embodiments wherein a backing element substrate includes at least one gasket fixedly attached thereto, the backing element substrate and/or the one or more fluid retaining structure(s) may be treated in accordance with the subject invention at the same or different times. Treatment of at least one member of a backing element/microarray assembly structure includes “global” and “local” treatment protocols. In other words, treatment of at least one member of a backing element/microarray assembly structure may be “global” such that the entire structure member may be treated, e.g., contacted with a treatment agent or “localized” such that only a specific area of the structure member may be treated, e.g., contacted with a treatment agent. By the term “contact” is meant broadly to include any suitable technique of bringing a treatment agent in sufficient proximity to at least one member of a backing element/microarray assembly structure to treat the particular member(s). For example, in certain embodiments this contact step includes immersing the backing element in a sufficient amount of a treatment agent or flooding a surface of a structure member with a treatment agent, and then removing the member from the treatment agent. For example, where the treatment agent is a fluid such as a fluidic organic solvent or aqueous solvent, the structure member or portion to be treated may be submersed in the fluid. Alternatively, contacting a structure member with a treatment agent may be accomplished using a drop deposition technique, e.g., using a pipette, swab, syringe, or other deposition technique, which may be useful, for example, in localized treatment protocols such as in embodiments where only small portion of the member is to be contacted with a treatment agent. In those embodiments where the treatment agent is a gaseous agent such as plasma treatment agents, the entire member may be positioned in a plasma chamber such that the entire member is contacted with plasma or a more localized technique may be employed. In certain embodiments, areas of a structure member not intended to be contacted may be “masked” or covered to prevent treatment agent from contacting or otherwise affecting the masked area.

In certain embodiments, at least one member of a backing element/microarray assembly structure to be treated is positioned in a treatment-compatible container, e.g., a container that holds the structure member vertically or the like with guides such that the members are separated by guides, tabs, rails, or the like. For example, backing elements may be positioned in such as container that has a minimum volume, i.e., the backing elements may be packed or stacked or otherwise positioned close together, with, e.g., about 1.5 mm to about 2.0 mm of space between the front of one backing element and the back of the next backing element.

Depending on the particular treatment g agent(s) employed, at least one member of a backing element/microarray assembly structure may be subjected to a variety of treatments, e.g., at different stages of a manufacturing process. In certain embodiments, such treatments include the removal of chemistries and films or other particulates, substances and adherent residues and the like from a backing element substrate surface and/or fluid retaining structure such as fluid retaining structure material (e.g., deposited in an incorrect location of a backing element substrate surface), fluid retaining structure precursor material that did not sufficiently change to a solid state, residual laser debris (e.g., from laser-scribed glass), oils, greases, waxes, dust, oxides, fingerprints, tarnish, rust, as well as many other organic and inorganic residues, substances and contaminants. For example, in regards to the removal of laser debris, in certain embodiments laser identification marks may be scribed on a backing element or microarray substrate, e.g., at the beginning of the production cycle, to maintain a reliable system of substrate tracking in order to effectively monitor the production line. These laser-scribed marks may contain information for later substrate identification such as lot number and job number that may be used to relate in-the-field product failures to processing history. In certain embodiments, a backing element substrate and/or microarray substrate may be fabricated by laser-scribing a substrate “precursor” and then singulating the laser-scribed substrate at the scribe marks to provide a plurality of backing element substrates or microarrat substrates. Regardless of the reason for laser scribing or marking a backing element substrate or the like, the process of substrate laser scribing results in laser debris and chemical residue on the backing element substrate surface that may adversely affect sealing of a microarray backing element to a microarray assembly, or adversely affect an array or its reading and thus must be removed prior to use of the microarray backing element or the like in an array assay protocol.

In further describing the subject invention, the term “contaminant” is used broadly to generally describe a component present on a substrate surface, regardless of its origin and make-up, in need of removal (i.e., an unwanted substance or substance that is deleterious to an array assay), where such term is not intended to be limiting in any manner. In certain embodiments, treatment includes removal of undesirable moieties from a gasket element such as materials that may leach from gasket during over time, e.g., leach over time and adversely interfere with an array or its reading. In certain embodiments, the subject treatment methods may alter the chemistry of a substrate (microarray or backing element) and/or gasket, e.g., to provide functional groups such as hydroxyl groups. Such functionalities may serve to remove unwanted substances from the backing element or the like and/or increase hydrophilicity and/or provide a fluid and/or gaseous “seal” or barrier about a gasket, etc.

As reviewed above, the subject invention includes a variety of different treatments, where embodiments include depositions, extractions and surface modifications. As noted above, these treatments may be performed on one or more members of a backing element/microarray assembly structure such as on a backing element substrate, gasket, microarray assembly (e.g., microarray substrate). A treatment may be performed on one or more members of backing element/microarray assembly structure at the same time, may only be performed on one of the members, or may be performed on various members at different times, including different treatments to different members at different times. Embodiments of these treatments are now described in greater detail.

Deposition Treatments

In certain embodiments, at least a portion of at least one member of a backing element/microarray assembly structure is treated by subjecting it to a deposition treatment, i.e., depositing at least one component on at least a portion of at least one member of a backing element/microarray assembly structure. Such depositions include poly-Si, SiO₂, Si₃N₄, and the like. For example, certain embodiments include depositing a coating (used herein interchangeably with layer and film) on a surface of at least one member of a backing element/microarray assembly structure, e.g., an SiO₂ coating, etc.

Such depositions may result in a coating on at least a portion of a substarte (a backing element or microarray substrate) and/or gasket surface. For example, embodiments include treating a microarray backing element having at least one gasket thereon by depositing an SiO₂ coating on at least a portion of, and in certain embodiments all of, the substrate surface, or at least on the gasket of the backing element. Embodiments include treating a gasket by depositing a coating on at least a portion of, and in certain embodiments all of, the gasket. Such a coating may be employed to provide enhancement of the sealing properties of a gasket, e.g., to prevent or at least minimize leaching of components from the gasket. The deposition material may form a crystalline or amorphous layer that impedes the flow of undesirable material from the inside of the gasket to the surface that may adversely affect an array or its reading when used with the gasket in an array assay protocol.

The thickness of a deposition coating will vary depending on the type of coating, process employed in the deposition, etc. In certain embodiments, the thickness of a deposition coating may be about several micrometers. Such thick coatings may encapsulate a gasket element and at least minimize leaching of components from the gasket into the array assay area. In certain embodiments, the thickness of a deposition coating ranges from 1 micron to about 200 microns, e.g., from about 5 microns to about 30 microns.

Any suitable deposition method may be employed and include physical, vapor and plasma enhanced deposition processes. For example, methods that may be employed for depositing a coating of poly-Si, SiO₂, Si3N₄, and the like onto at least one member of a backing element/microarray assembly structure, include, but are not limited to, atmospheric pressure chemical vapor deposition methods (APCVD), low-pressure chemical vapor deposition (LPCVD), plasma enhanced chemical vapor deposition (PECVD), or any other suitable method.

Extraction Treatments

In certain embodiments, at least a portion of at least one member of a backing element/microarray assembly structure is treated by subjecting it to an extraction treatment, i.e., at least one component is extracted or removed from at least one member of a backing element/microarray assembly structure. Such treatments include liquid phase extractions, vapor phase extractions, heat treatment, and the like. Components may be removed from at least a portion of at least one member of a backing element/microarray assembly structure and may include removing a component from the backing element substrate and/or microarray substrate and/or a gasket.

Accordingly, embodiments include liquid phase extractions. Embodiments of liquid phase extractions include contacting at least one member of a backing element/microarray assembly structure with at least one solvent to treat the at least one member. Suitable solvents include, but are not limited to, organic solvents and inorganic solvents, including super critical fluids such as super critical CO₂.

Treatments using one or more solvents may remove contaminants from the backing element substrate surface or the like and/or from or within a gasket. For example, solvent treatment may remove moieties within a gasket that are prone to migration or diffusion through the gasket. Left untreated, these moieties may migrate from the gasket into the array assay area adversely affecting the array or its reading. Such moieties that may be removed from a gasket include, but are not limited to, low melting point monomers or truncated polymers or and/or additives used in the fabrication of the gasket such as gasket precursor materials, or species generated as byproducts of a given gasket forming process, i.e., produced as byproducts of a gasket curing process, as well as byproducts produced as a result of a previous treatment protocol such as a previously performed plasma treatment protocol. By low melting point is meant low melt monomers and truncated polymers that are liquid at the temperature at which the array assay is performed, e.g., at the hybridization temperature. For example siloxanes D4-D10, and the like, are low melting point monomers in accordance with the subject invention. By truncated polymer or short chain polymer is meant a chain of a given polymer that is shorter than the average chain. Accordingly, such truncated polymers may still be liquid and thus pose a problem for array assays, e.g., for hybridization assays. A particular polymer may be truncated for any reason and include instances where the polymerization has been stopped abruptly intentionally or not and instances where the short chain occurs as part of the polymerization process. Truncated polymers as used in accordance with the subject invention include, but are not limited to, the polymer polydimethylsiloxane that has been scised or cut by a chemical reaction resulting in small fragments (which may be removed by, e.g., plasma treatment as described below). The subject treatment protocols are particularly useful for the removal of low melting point monomers such as D4-D20 series linear or cyclic siloxanes. By D4-D20 series linear or cyclic siloxanes is meant a series of siloxanes defined as Dn=((CH₃)₂SiO)ₙ for cyclic molecules. For example, octamethylcyclotetrasiloxane (D4), decamethylcyclotetrasiloxane (D5), Dodecamethylcyclohexasiloxane (D6), and the like. A series of linear molecules are also included, e.g., dodecamethylpentasiloxane (L5), and the like. For example, in polydimethylsiloxane elastomeric gasket curing protocols, byproducts produced by the curing process may include D4-D20 series linear and cyclic siloxanes, where these siloxanes may adversely affect an array assay and as such may be removed according to the subject invention. Solvent treatments may also be employed to remove other contaminants as reviewed above, e.g., grease, oils, salts, residues, laser ablation debris, and the like. For example, either organic or aqueous solvent solutions may be employed to effectively and efficiently remove particulates from a substrate surface, e.g., residue remaining on the surface after laser ablation of identification marks.

A variety of different organic solvents may be employed, where in certain embodiments more than one solvent is employed, e.g., two or more solvents may be employed in a mixed or sequential manner. While the selection of a particular solvent to be used will depend on a variety of factors such as the material of the at least one member of a backing element/microarray assembly structure being treated, the desired modification, etc., the one or more organic solvents employed are chosen so as to be effective and efficient at treating a substrate surface (e.g., effective and efficient at removing a contaminant from a substrate surface), yet does not damage or harm the cured gasket material if present during the treatment. For example, the one or more solvents employed may be chosen so as not to solvate the cured gasket material, but which will solvate the contaminant. A variety of organic solvents may be used and include polar and non-polar organic solvents. For example, polar organic solvents that may be employed include, but are not limited to, such polar organic solvents as alcohols, e.g., methanol, ethanol, isopropanol, and the like; ketones, e.g., methyl ethyl ketone, acetone, and the like; trialkyl amines, e.g., trietylamine and the like; tributyl amines; and various aromatic and cyclic polar solvents such as pyrolidinone and the like. Non-polar organic solvents that may be employed include, but are not limited to, aliphatic hydrocarbons, e.g., hexane, heptane, and the like; aromoatic hydrocarbons, e.g., toluene, benzene, xylene, cyclohexane, and the like; methyl, ethyl, and other ethers; glymes including diglyme, triglyme, and the like. Fluorosilicone compounds may also be used.

As described above, aqueous solvents may also be employed. Aqueous solvents employed will at least include a minimal amount of water. For example, the amount of water may range from about 5% to about 95%, e.g., from about 15% to about 75%, e.g., from about 25% to about 50%. The water that is used to produce the subject fluids may be obtained from any convenient water source such that the water may be tap water obtained from, for example, a municipal water district. The water employed in the subject invention will typically need to be purified or otherwise treated, e.g. to remove certain undesirable agents that may be initially present therein such as certain organic and inorganic chemicals, heavy metals, etc. Such purification or treatment protocols include, but are not limited to, deionization, distillation, and the like, where such protocols are well known to those of skill in the art. Suitable aqueous solvents include, but are not limited to 100% water, various cleaning mixtures, aqueous solutions of surfactants, and other binary, ternary, or other multi-component mixtures in which water is one component.

Certain aqueous mixtures may include one or more surfactants. The surfactant chosen and the concentration thereof will depend on the material used to form the fluid retaining structure is being treated and the particular surfactant(s) employed, where in certain embodiments a buffered surfactant may be used. Surfactants employed include ionic and non-ionic surfactants. For example, in those embodiments employing an ionic surfactant, suitable ionic surfactants include, but are not limited to, sodium or lithium dodecylsulfate, trialkyl ammonium chloride, and the like and in those embodiments employing a non-ionic surfactant, suitable non-ionic surfactants include, but are not limited to, surfactants having the formula C₁₄H₂₂O(C₂H₄O)ₙ having an average number of ethylene oxide units per molecule or about 9 or 10 such as Triton® X-100 (also known as Alkylaryl polyether alcohol; Octyl phenol ethoxylate; Triton X-100 Surfactant; Polyoxyethylated octyl phenol; alpha-[4-(1,1,3,3-tetramethylbutyl)phenyl]-omega-hydroxypoly(oxy-1,2-ethanediyl); Octoxinol; Triton X 100; Triton X 102; Ethylene glycol octyl phenyl ether; Polyoxyethylene octyl phenyl ether; p-(1,1,3,3-Tetramethylbutyl)phenol ethoxylate; Octylphenoxypolyethoxyethanol; Polyethylene glycol mono [4-(1,1,3,3-tetramethylbutyl)phenyl] ether; Poly(oxyethylene)-p-tert-octylphenyl ether; POE octylphenol; polyoxyethylene (10) octylphenol; POE (10) octylphenol; POE(10) Octyl Phenyl Ether; Octoxynol-10; POE(3) Octyl Phenyl Ether; Octoxynol-3; POE(30) Octyl Phenyl Ether; Octoxynol-30), propylene glycol, and the like. These surfactants may also be partially or completely fluorinated ionic and non-ionic types as well.

Any solvent employed may include a suitable buffering system to maintain the pH of the solvent in an suitable range, where a particular pH will vary depending on the solvent(s) used and include acidic, neutral and basic pH.

The steps involved in treating at least one member of a backing element/microarray assembly structure using an organic and/or inorganic solvent generally include contacting the particular structure member or portion thereof with a suitable amount of an organic and/or inorganic solvent, removing the member from the solvent and drying the member, e.g., air drying, nitrogen drying, vacuum drying etc., to remove any solvent present on the surface of the member.

In certain embodiments, the dried structure member may then be contacted with another clean (i.e., “fresh”) solvent, i.e., a second organic or inorganic solvent, which may be the same type of solvent previously used or different type of solvent. Regardless of whether there is contact with one or two solvents, following contact of the member with the final solvent, in many embodiments a small amount, e.g., a mist, of solvent (which may be the same or different type of solvent from that used previously) may be contacted with the member to ensure removal of all of the previously contacted solvent. After misting with a solvent, the backing elements are dried using any suitable technique such as nitrogen or air drying, with or without heat.

The amount of solvent employed (exclusive of the misting step) may vary depending on the particular solvent employed, the surface area to be modified, etc. For example, when contacted with a backing element, the amount of solvent used may range from about 0.005 ml/mm² backing element contacted to about 0.15 ml/mm² backing element contacted, e.g., from about 0.008 ml/mm² to about 0.10 ml/mm² backing element contacted, e.g., from about 0.01 ml/mm² to about 0.05 ml/mm² backing element contacted. The amount of time a solvent is in contact with a backing element may range from about 1 minute to about 480 minutes, e.g., from about 5 minutes to about 240 minutes, e.g., from about 15 minutes to about 120 minutes. In a misting step, if employed, the amount of solvent used may range from about 0.0005 ml/mm² to about 0.0015 ml/mm² backing element contacted, e.g., from about 0.0008 ml/mm² backing element contacted to about 0.01 ml/mm² backing element contacted, e.g., from about 0.001 ml/mm² to about 0.005 ml/mm² backing element contacted. The amount of time a solvent is in contact with a backing element may range from about 1 second to about 30 seconds, e.g., from about 5 seconds to about 20 seconds, e.g., from about 8 seconds to about 15 seconds.

A general solvent modification protocol may include contacting at least one member of a backing element/microarray assembly structure with a suitable amount of solvent. The at least one member may then be air dried for about 15 to about 25 minutes, e.g., about 20 minutes. The air dried member may then be contacted with a suitable amount of clean or fresh solvent that may be the same as previously employed for a period of time ranging from about 5 minutes to about 90 minutes. Upon removal of the at least one member from the solvent, a mist of clean solvent that may be the same solvent as previously employed may be sprayed over the member. The member may then be dried with a nitrogen or air gun and again air or nitrogen dried, with or without heat.

For example, for toluene treatment of a backing element that includes a glass or silica substrate and one or more elastomeric gaskets, the following backing element treatment protocol employing toluene may be followed. As a first step, the backing element to be treated may be positioned in or on a suitable carrier for easy handling such as a stainless steel carrier or other such carrier that will not degrade upon contact with toluene. The carrier with backing element may then be positioned in a suitable, empty solvent tank. Once the backing element is positioned in the tank, the tank may be filled with a suitable volume of toluene such that the backing element is covered by the toluene, e.g., a sufficient amount of toluene is such that the toluene level is about ¼ inch or more above the topmost surface of the backing element as it is positioned in the tank. The duration of contact between the backing element and the toluene may range from about 1 hour to about 2 hours, e.g., one hour with agitation (e.g., rocking, stirring etc.) of the tank every fifteen minutes or two hours with agitation of the tank at the end of two hours. After contact with the first volume of toluene, the tank may then be emptied of toluene. The tank may then be filled with a clean or fresh volume of toluene in a manner analogous to that described above for the first volume of toluene. Contact duration of the backing element with this second volume of toluene may be about thirty minutes with suitable agitation of the tank, e.g., agitation of the tank about every ten minutes. The tank may then be emptied of this second volume of toluene and the carrier with backing elements removed. The backing elements may be air dried for about one hour or more to remove any remaining solvent from the backing element. Analogous methods may be employed for solvents other than toluene.

Regardless of the particular solvent treatment employed, once at least one member of a backing element/microarray assembly structure is contacted with a suitable solvent and the solvent treatment performed, the solvent treated member may then be removed from the solvent tank as described above. In certain embodiments, the solvent treated member is then subjected to at least one other treatment, e.g., contacted with at least one more treatment agent such as a plasma or a different solvent such as a different organic solvent. Accordingly, as reviewed above, the treatment of a structure member may include contact with at least two different treatment agents, where solvent treatment may be performed prior to or after treatment by any other process, e.g., by any other treatment agent. In other words, the above-described solvent treatment may be performed prior or subsequent to another treatment process or even at the same time as another treatment protocol. However, in certain embodiments solvent treatment may be the only treatment employed to treat a given member of a backing element/microarray assembly structure.

In certain embodiments treatment may include vapor phase extractions. Embodiments of vapor phase extractions include contacting at least one member of a backing element/microarray assembly structure with at least one material in its vapor phase to treat the member. Accordingly, one or more solvents, e.g., any of the solvents described above, may be vaporized and contacted with at least one member of a backing element/microarray assembly structure to treat it.

Treatments using one or more vapors may remove contaminants from the backing element substrate surface or the like and/or from or within a gasket. Analogous to that described above for liquid phase treatments, vapor phase treatments may remove moieties within a gasket that are prone to migration or diffusion through the gasket. As noted above, left untreated these moieties may migrate from the gasket into the array assay area adversely affecting the array or its reading. Such moieties that may be removed from gasket include, but are not limited to, low melting point monomers or and/or additives used in the fabrication of the gasket such as gasket precursor materials, or species generated as byproducts of a given gasket forming process, i.e., produced as byproducts of a gasket curing process, as well as byproducts produces as a result of a previous treatment protocol such as a previously performed plasma modification protocol. Analogous to that described above, vapor phase treatment protocols are particularly useful for the removal of low melting point monomers such as D4-D20 series linear or cyclic siloxanes. As noted above, in polydimethylsiloxane elastomeric gasket curing protocols, byproducts produced by the curing process may include D4-D20 series linear and cyclic siloxanes, where these siloxanes may adversely affect an array assay and as such may be removed by employing the subject vapor extraction methods. Vapor phase treatments may also be employed to remove other contaminants as reviewed above, e.g., grease, oils, salts, residues, laser ablation debris, and the like. For example vapor phase extraction equipment may be employed to effectively and efficiently remove particulates from a substrate surface, e.g., residue remaining on the surface after laser ablation of identification marks.

A variety of different vapors may be employed, where in certain embodiments more than one vapor is employed, e.g., two or more vapors may be employed in a sequential manner. While the selection of a particular vapor phase to be used will depend on a variety of factors such as the material of the member of a backing element/microarray assembly structure being treated, the desired treatment, etc., where the one or more vapors employed are chosen so as to be effective and efficient at treating at least one member of a backing element/microarray assembly structure, e.g., a substrate surface (e.g., effective and efficient at removing a contaminant from a substrate surface) and/or gasket, yet does not damage or harm the backing element, e.g., does not damage cured gasket material.

In vapor extraction methods, generally at least one member of a backing element/microarray assembly structure is contacted with a sufficient amount of a vaporized solvent under conditions sufficient to treat the at least one member of a backing element/microarray assembly structure. Any suitable technique for vapor phase extraction may be employed, and include vapor immersion such as with a vapor immersion unit as is known in the art (e.g., an ultrasonics-equipped unit), which usually includes two solvent-filled sumps (the boil sump and the cold sump which is filled with clean, distilled condensate solvent and is often used for rinsing) and a vapor/spray methods such as with a vapor/spray unit, in which the solvent is boiled in the very bottom of a one-sump unit. Accordingly, such embodiments may include positioning at least one member of a backing element/microarray assembly structure to be treated in a perforated metal holder positioned above the boiling solvent. The basket of one or more members is not immersed in solvent, but rather the vapor made by the boiling solvent completely encompasses the member(s) completely and extracts the desired component(s) therefrom. The extracted component(s), now diluted into the condensing liquid, drips back into the boiling solvent below. A manual spray wand may be provided which is sprayed under the cooling coils, directly on extractable component(s). Units employed in vapor extractions will vary in size and type from small, manually operated machines to automated, conveyorized systems. The simplest unit may include a rectangular or analogously shaped tank with a sump of boiling solvent in the bottom. The cleaning space, or vapor zone, is just above the boiling solvent. Units may also include a refrigerant or water cooled external jacket or internal coils are located above the vapor zone to confine solvent vapor to the tank and prevent vapor loss to the atmosphere. Heat input for vapor phase extraction units may be supplied by electricity, steam, and gas or by a heat pump. When an ultrasonic-equipped vapor phase unit is employed, the parts are immersed in a container of the solvent so that ultrasonic energy is delivered efficiently to the parts.

Surface Modification Treatments

In certain embodiments, at least a portion of at least one member of a backing element/microarray assembly structure is treating by surface modifying at least a portion of the member. A variety of different surface treatments may be employed, depending on the desired result.

Plasma Treatments

In certain embodiments, at least a portion of at least one member of a backing element/microarray assembly structure is contacted with at least one plasma to modify a surface thereof, herein describe primarily with respect to plasma treating a backing element substrate having at least one gasket thereon for exemplary purposes. Accordingly, embodiments include contacting a microarray backing element with at least one plasma under conditions sufficient to modify a surface thereof. In accordance with such embodiments, the partially or wholly ionized gas particles interact with the surface of the backing element to modify it, e.g., increase or enhance wettability. Plasma may be used for a variety of surface modifications, as described above, such as removing organic substances from a backing element, surface chemical restructuring, etc. For example, oxygen plasma may be employed to remove organics from a backing element surface. Specifically, oxygen plasma may be used as a modifying agent that may cause a chemical reaction to occur with surface contaminants resulting in their volatilization and removal from the surface of the backing element. For example, oxygen plasma readily combines with any organic hydrocarbon, resulting in water vapor, CO and CO₂, which may then be removed from the plasma reactor. In certain embodiments, modification may include promoting cross-linking on a surface of the backing element. For example, plasma generated by inert noble gases such as helium and argon may be employed to remove certain moieties from the backing element surface and generate reactive radicals. These radicals may react with a surface of the backing element forming chemical bonds resulting in a stable cross-linking of the surface and thus improved bond strength. As noted above, plasma may also be used for surface chemical restructuring, e.g., by adding polar functional groups to a surface of the backing element thus increasing hydrophilicity, e.g., as measured by contact angles, e.g., receding contact angles, which measures the tangent angle of a drop of water (or hybridization solution as used in an array hybridization assay (e.g., hybridization solution available from Agilent Technologies, Inc.) relative to a surface. For example, embodiments may include providing contact angles (measured with pure water) as low as about 15 degrees to about 30 degrees. For example, a surface that is unmodified by plasma treatment may show a receding contact angle of 40-50 degrees when using a hybridization solution for the contact angle test. The same surface modified by a plasma treatment in an oxygen atmosphere in accordance with the subject invention may show a receding contact angle of 25-30 degrees when using a hybridization solution for the test.

Plasma modification may be used to provide oxidation of a surface of a backing element. As noted above, this oxygenation of the backing element surface may be employed to provide a seal about a gasket to minimize or eliminate diffusion of gases and fluids through the gasket.

Embodiments include employing a plasma treatment to raise the surface energy of a backing element and thus reduce the contact angle between the backing element surface and solutions, e.g., hybridization solutions, used in array assays. In this manner, the array assay solution more easily wets the backing element surface, e.g., a gasket surface, as compared to non-plasma treated surfaces. This reduces incidence and severity of bubbles sticking to a backing element surface, which in turn at least minimizes non-uniform array assay binding between binding pair partners, e.g., non-uniform hybridization, which may occur adjacent stuck bubbles in an array assay area.

According to embodiments of the subject invention, a plasma may interact with the surface molecules of a backing element, increasing their energy through a variety of mechanisms, depending on the specific material of the backing element involved. In some cases, surface hydrogen molecules are removed, leaving behind active bonding sites. Also, crosslinking or scission can occur in the surface molecules. This changes the surface energy of the material, e.g., making it easier for a coating to adhere. Oxides may also form on the surface which are easier to bond to than the untreated surface.

Plasma modification may be used to provide oxidation of a surface of a backing element. As noted above, this oxygenation of the backing element surface may be employed to provide a seal about a gasket to eliminate or at least minimize diffusion of gases and fluids through the gasket.

Any suitable plasma or mixture of plasmas may be employed, where the selection of a given plasma or mixture of plasmas to be employed is dependant upon the particular materials of the backing element, the intended surface modification, etc. Representative plasmas include, but are not limited to, air, nitrogen, argon, oxygen, nitrous oxide, helium, tetrafluoromethane, water vapor, carbon dioxide, methane, and ammonia. For example, if it is desired to increase wettability and chemical reactivity of a surface of a backing element, e.g., a glass substrate with an elastomeric gasket, such may be accomplished by employing plasma-induced oxidation, nitration, hydrolyzation or amination of the surface. Embodiments include the use of oxygen to increase hydrophilicity of a surface of the backing element. On the other hand, plasma-induced fluorination of a backing element that includes a glass substrate with an elastomeric gasket may be employed to increase hydrophobicity of the surface if desired.

In practicing the subject methods to modify a backing element surface using plasma, a backing element is contacted with plasma. This is typically accomplished by positioning the backing element to be modified in a plasma reactor. Such reactors are well known in the art and may generally be described as a vacuum chamber that includes a vacuum pump, purge means, process gas sources and regulators, a source of energy for gas ionization such as electromagnetic energy, and typically includes means (e.g., microprocessor(s), software, circuitry, etc.) to implement and control the process parameters such as the time, gas flow, and amount of energy automatically.

While the exact parameters of a plasma protocol may vary depending on the gas employed, modification desired, etc., the plasma modification process according to the subject methods may generally be described by the following seven steps: 1) pump down the reactor to a predetermined vacuum pressure (base pressure); 2) introduce the process gas (which may be a single gas or a plurality of different gases) and allow the gas to stabilize at a desired process pressure; 3) initiate plasma by providing a suitable energy source such as radio frequency (“RF”) energy; 4) shut off RF power and process gas delivery after plasma treatment for the desired length of time; 5) pump down to base pressure to eliminate residual process gas(es); 6) vent to atmosphere, and 7) remove plasma modified backing element.

The ionization of the gas(es) may be accomplished by providing an energy field using any suitable energy source such as an RF generator, microwave generator, DC power generator, etc. For example, a suitable RF generator may be employed and includes low frequency RF generators (90 KHz-1 MHz), mid-frequency RF generators (1-4 MHz), high frequency RF generators (13.56 MHz), and extended-frequency RF generators (27.12-40.68 MHz). Power may range from a few watts to kilowatts. For example, Where RF is employed, RF power may range from about 20 watts to about 1000 watts, e.g., from about 50 to about 500 watts, e.g., from about 100 watts to about 400 watts.

As noted above, the particular plasma parameters will vary depending on the particular plasma modification performed, e.g., the gas, desired modification, etc. In many embodiments, the duration of the plasma modification may range from about 1 minute to about 60 minutes, e.g., from about 3 minutes to about 30 minutes, e.g., from about 5 minutes to about 25 minutes, the temperature at which the plasma modification is performed may range from about 20° C. to about 200° C., e.g., from about 30° C. to about 150° C., e.g., from about 50° C. to about 130° C., the power (RF power for exemplary purposes) may range from about 20 watts to about 1000 watts, e.g., from about 50 watts to about 300 watts, e.g., from about 100 watts to about 250 watts, the gas flow rate may range from about 0.1 ml/min to about 300 ml/min, e.g., from about 0.3 ml/min to about 200 ml/min, e.g., from about 10 ml/min to about 100 ml/min, and the system pressure may range from about 0.01 torr to about 20 torr, e.g., from about 0.05 torr to about 10 torr, e.g., from about 0.1 torr to about 1 torr.

For example, in certain embodiments surface modification includes oxidizing or providing hydroxyl groups on a surface of a backing element (i.e., a surface of the backing element substrate and/or gasket). As reviewed above, surface modification that includes oxidation of a backing element surface may clean the backing element by removing unwanted substances and increase hydrophilicity (e.g., to array binding fluids such as fluid samples and array binding fluids such as buffers and the like). Such also provides an improved seal or barrier about the gasket, i.e., changes the chemistry of the gasket to a surface that effectively slows or eliminates diffusion of undesirable moieties, such as gasket material precursor moieties (that did not effectively change to a solid material), from the gasket, and may also serve to eliminate or minimize gas and fluid diffusion through the gasket, thus minimizing losses of fluid and mixing bubbles, if employed, from the gasket, during an array assay, by diffusion through the gasket. This may be accomplished by producing hydroxyl groups about the gasket and/or modulating the free volume, or jump distance of the gasket. For example, a plasma modification may modulate the free volume of a gasket, e.g., decrease the molecular level pore size, to sizes small enough to minimize fluid diffusion through the gasket. The plasma induced surface modification may also be employed to remove areas of the backing element where cured gasket material may have been unintentionally deposited. For example, if this unintentionally deposited cured material is present in the interior of a gasket, it may affect the wetting and dewetting properties of the gasket and may adversely affect mixing of a fluid in the gasket such as by bubble mixing.

For example, using plasma modification to oxidize a backing element that includes a glass or silica substrate and an elastomeric gasket, the plasma oxidation may be carried out in a radio-frequency plasma chamber in an oxygen atmosphere. For such an oxidation modification of a backing element, the duration of a plasma modification may range from about 5 minutes to about 25 minutes, e.g., about 20 minutes, the temperature may range from about 80° C. to about 150° C., the RF power may range from about 200 W to about 500 W, the oxygen gas flow rate may range from about 70 cc/min. to about 80 cc/min, e.g., about 75 cc/min., and the system pressure may range from about 0.1 Torr to about 1 Torr. The above described oxygen plasma modification provides functionalization on the backing element substrate and gasket surfaces with oxygen-containing chemical groups, as well as removing contaminants from the backing element.

Regardless of the particular plasma surface modification, once a backing element is contacted with suitable plasma and the plasma modification performed, the plasma modified backing element may then be removed from the plasma reactor. In certain embodiments, the plasma modified backing element is subjected to at least one more treatment, e.g., it may be further contacted with at least one more treatment agent such as an organic solvent, inorganic solvent, and the like, such that the treatment of a given backing element may include contact with at least two different agents, where the plasma modification may be performed prior to or after treatment by any other treatment method. In other words, the above-described plasma modification may be performed prior or subsequent to, even at the same time as, another treatment process. However, in certain embodiments plasma modification may be the only treatment employed to treat a given backing element.

Gas/Air Treatments

In certain embodiments, at least a portion of at least one member of a backing element/microarray assembly structure is contacted with at least one gas/air combination, i.e., mixture, to modify a surface thereof, herein describe primarily with respect to gas/air treatments of a backing element substrate having at least one gasket thereon for exemplary purposes. Accordingly, embodiments include contacting a microarray backing element with at least one gas/air combination under conditions sufficient to modify a surface thereof and may be employed in certain embodiments to at least modify a surface of a gasket.

Gas/air surface treatments include, but are not limited to flame treatments. Flame treatments may involve the brief application of a flame or heat to the backing element which may oxidize a thin surface layer of the material, creating highly active surface molecules. Flame treatments may reduce the contact angle to below about 50 degrees. Flame post treatments may be employed to increase SiO₂ and Si concentration at a silicone surface. Methods of performing flame treatments are known in the art and will not be described in great detail herein. Any suitable flame treatment protocol may be employed and include, but are not limited to, flame treatments using methane, propane, butane, and the like.

Particulate Blasting Treatments

In certain embodiments, at least a portion of at least on member of a microarray backing element/microarray assembly structure may be treated by particle blasting, e.g., using beads, herein describe primarily with respect to particulate blasting a backing element substrate having at least one gasket thereon for exemplary purposes. Particle blasting as used herein broadly refers to the use of pressurized gas to project particles, e.g., beads, sometimes—though not always—of a relatively uniform diameter, at a microarray backing element at a velocity sufficient to modify a surface of the backing element (grit blasting generally does not include grit of relatively uniform diameter). Particle blasting treatments of a substrate surface and/or a gasket may be employed to increase the surface area of the blasted area and effectively increase the surface energy of the blasted area. Furthermore, a textured surface is known to exhibit much greater hydrophilicity than a smooth surface.

Such embodiments include contacting at least a portion of a backing element with a plurality of particles, e.g., beads, under conditions sufficient to modify the contacted surface, e.g., to increase surface area and/or surface energy. For example, embodiments include impinging or “blasting” glass, aluminum oxide, grit, silicon carbide, sand, latex, titanium oxide, or other hard or semi-hard particles against at least a portion of a microarray backing element. The beads are typically carried in a pressurized stream of air or other gas. Pressure may range from about 40 to about 140 psi. The beads may be spherical, granular, or any other desired shape and dimension. One bead material that may be used is glass to provide glass beads, e.g., mesh size 60-120 (for example available from McMaster under part no. 3398K72), although other mesh sizes may be employed as well, e.g., mesh sizes of 40-60 to 170-325, and the like may be employed.

The surface modification achieved may be controlled by the size of the particles, e.g., the diameter of the particles, the pressure used, the distance between the particle source and the backing element, and the length of time the particles are blasted at the backing element. By way of example and not limitation, the particles may be beads having a mesh size of between about 60 and about 120. Pressures may be under about 90 psi may be used to project the beads from a distance of about 150 mm distance from the nozzle.

Other surface roughening processes may be used as well and include chemical etching, lithography, laser ablation, etc.

Radiant Energy Treatments

In certain embodiments, at least a portion of at least on member of a microarray backing element/microarray assembly structure may be treated by exposing it to radiant energy to modify a surface thereof, herein describe primarily with respect to radiant energy treatments of a backing element substrate having at least one gasket thereon for exemplary purposes. Radiant energy surface modifications include, but are not limited to, electromagnetic radiant energy, ultrasonic radiant energy, x-ray energy, and the like.

For example, certain embodiments include exposing a microarray backing element to electromagnetic radiant energy, e.g., visible light, uv light, deep uv light, and the like. Such may be used to surface modify the substrate and/or gasket, and is particularly useful for modifying a gasket. Accordingly, a microarray backing element may be exposed to electromagnetic radiation of any suitable wavelength. Such may be achieved by employing a laser such as an excimer laser, and with or without gas, e.g., uv/vacuum, uv/O₂, uv/argon, etc.

For example, a treatment may include exposing a backing element of a glass or silica substrate and a polymeric gasket such as an elastomeric gasket to ultraviolet energy and oxygen gas to oxidize the backing element. The oxidation treatment may be carried out in an ultraviolet light chamber in an oxygen atmosphere. For such an oxidation treatment of a backing element, the duration of a UV exposure treatment may range from about 15 minutes to about 120 minutes, e.g., about 30 minutes, the temperature may range from about 20° C. to about 50° C., the UV power may range from about 5 mw/cm² to about 50 mw/cm², the wavelengths of the UV light including 184.9 nm and 253.7 nm, and the oxygen (air) pressure at or around ambient, e.g., about 760 Torr. The above described UV/O₂ modification provides functionalization on the backing element substrate similar to that of a plasma modification, and generates gasket surfaces with O-containing chemical groups, as well as removes contaminants from the backing element.

Solubalizing Soluble Particles

In certain embodiments, at least a portion of at least on member of a microarray backing element/microarray assembly structure may be treated by solubalizing soluble particles in or about at least on member of a microarray backing element/microarray assembly structure such as a gasket. Such may be desired to provide a roughened or textured surface. As noted above, a textured surface is known to exhibit much greater hydrophilicity than a smooth surface. For example, as noted above, certain embodiments include a curable gasket. Accordingly, a gasket may be provided with a rough surface by adding soluble particles, e.g., a salt or sugar, prior to curing. The gasket may be cured and the gasket may be further treated by contacting it with a solubalizing fluid to solubalize the added soluble particles resulting in a textured surface.

Electron Bombardment Treatments

In certain embodiments, at least a portion of at least on member of a microarray backing element/microarray assembly structure may be treated by exposing it to electron bombardment. Electron bombardment involves the direction of a beam or “cloud” of electrons onto the backing element to interact with the surface. The free electrons in the cloud or beam act to knock existing electrons out of their orbital positions, e.g., to provide locations on the surface where other chemicals may bond. The electron beam may also cross-link or cut some polymer chains, creating additional locations for chemical bonding. This process is carried out in a vacuum environment to minimize the effects of air molecules. Accordingly, electron beam treatments may be employed in situations analogous to plasma treatments, with analogous treatment results.

For example, exposing at least on member of a microarray backing element/microarray assembly structure, e.g., microarray backing element to electron beam bombardment may be employed to provide functional groups on the surface of the backing element, e.g., to enhance wettability of the surface.

Reactive Gas Treatments

In certain embodiments, at least on member of a microarray backing element/microarray assembly structure may be treated by contacting at least a portion of it with a reactive gas.

Treated Microarray Structure Members

Also provided by the subject invention is treated microarray structure members that have been treated in accordance with one or more treatment methods described above, such as treated backing element substrates, treated microarray substrates, treated gaskets (regardless of whether fixedly attached to a microarray backing element substrate or microarray substrate or whether a separable component). For example, embodiments include treated backing elements that include at least a portion or area of the backing element that has been altered, changed, enhanced, etc., (i.e., the substrate and/or the fluid retaining structure) according to one or more of the subject treatment protocols, where such treatment may include treating a surface of the substrate and/or a fixedly or readily removable fluid retaining structure, including a surface within a fluid retaining structure, e.g., removal of moieties from within a fluid retaining structure that may adversely affect or are at least suspected of adversely affecting a microarray or its reading. Treatment include, but are not limited to, cleaning, e.g., removal of unwanted substances or substances that may be deleterious to, or adversely affect, an array assay, providing functional groups such as hydroxyl groups, changing wettability (i.e., increasing or decreasing hydrophilicity), etc., providing a fluid and/or gas impermeable seal about a fluid retaining structure, for example an improved or enhanced fluid and/or gas permeable seal as compared with a seal that is not treated, etc., as described above.

Utility

As described above, treated microarray structure components may be employed in array assay protocols. For example, backing element substrates (treated or not) may be employed with a microarray assembly (treated or not) and a gasket (treated or not) to provide a backing element/microarray assembly structure that forms an array assay chamber about one or more microarrays of the microarray assembly. The array assay chamber may then be used in a variety of different array assay protocols as will be described in greater detail below. For example, a treated backing element substrate may be positioned adjacent a microarray substrate (treated or not) such that the one or more gaskets (treated or not) are operatively positioned between a surface of the backing element substrate and a surface of the microarray substrate.

Microarrays include at least two distinct polymers that differ by monomeric sequence attached to different and known locations on the microarray substrate surface. Each distinct polymeric sequence of the array is typically present as a composition of multiple copies of the polymer on a substrate surface, e.g., as a spot or feature on the surface of the substrate. The number of distinct polymeric sequences, and hence spots or similar structures, present on the array may vary, where a typical array may contain more than about ten, more than about one hundred, more than about one thousand, more than about ten thousand or even more than about one hundred thousand features in an area of less than about 20 cm² or even less than about 10 cm². For example, features may have widths (that is, diameter, for a round spot) in the range from about 10 μm to about 1.0 cm. In other embodiments, each feature may have a width in the range from about 1.0 μm to about 1.0 mm, usually from about 5.0 μm to about 500 μm and more usually from about 10 μm to about 200 μm. Non-round features may have area ranges equivalent to that of circular features with the foregoing width (diameter) ranges. At least some, or all, of the features are of different compositions (for example, when any repeats of each feature composition are excluded, the remaining features may account for at least about 5%, 10% or 20% of the total number of features). Interfeature areas will typically (but not essentially) be present which do not carry any polynucleotide (or other biopolymer or chemical moiety of a type of which the features are composed). Such interfeature areas typically will be present where the microarrays are formed by processes involving drop deposition of reagents, but may not be present when, for example, photolithographic array fabrication process are used. It will be appreciated though, that the interfeature areas, when present, could be of various sizes and configurations. The spots or features of distinct polymers present on the array surface are generally present as a pattern, where the pattern may be in the form of organized rows and columns of spots, e.g. a grid of spots, across the substrate surface, a series of curvilinear rows across the substrate surface, e.g. a series of concentric circles or semi-circles of spots, and the like.

In the broadest sense, the microarrays are arrays of polymeric or biopolymeric ligands or molecules, i.e., binding agents, where the polymeric binding agents may be any of: peptides, proteins, nucleic acids, polysaccharides, synthetic mimetics of such biopolymeric binding agents, etc. In many embodiments of interest, the microarrays are arrays of nucleic acids, including oligonucleotides, polynucleotides, cDNAs, mRNAs, synthetic mimetics thereof, and the like.

The microarrays may be produced using any convenient protocol. Various methods for forming microarrays from pre-formed probes, or methods for generating the array using synthesis techniques to produce the probes in situ, including known light directed synthesis processes, are generally known in the art. For example, probes may either be synthesized directly on the microarray solid support or substrate or attached to the substrate after they are made. Arrays can be fabricated using drop deposition from pulsejets of either polynucleotide precursor units (such as monomers) in the case of in situ fabrication, or the previously obtained polynucleotide. Such methods are described in detail in, for example, the previously cited references including U.S. Pat. No. 6,242,266, U.S. Pat. No. 6,232,072, U.S. Pat. No. 6,180,351, U.S. Pat. No. 6,171,797, U.S. Pat. No. 6,323,043, U.S. patent application Ser. No. 09/302,898 filed Apr. 30, 1999 by Caren et al., and the references cited therein. These references are incorporated herein by reference. Other drop deposition methods can be used for fabrication, as previously described herein. Also, instead of drop deposition methods, light directed fabrication methods may be used, as are known in the art. Interfeature areas need not be present particularly when the arrays are made by light directed synthesis protocols. Accordingly, as described above, the probes may be synthesized directly on a substrate, or pre-made probes may be attached to the substrate, after the substrate has been treated according to the subject invention.

Immobilization of the probe to a suitable substrate may be performed using conventional techniques. See, e.g., Letsinger et al. (1975) Nucl. Acids Res. 2:773-786; Pease, A. C. et al., Proc. Nat. Acad. Sci. USA, 1994, 91:5022-5026, and Oligonucleotide Synthesis, a Practical Approach,” Gait, M. J. (ed.), Oxford, England: IRL Press (1984). The surface of a substrate may be treated with an organosilane coupling agent to functionalize the surface. See, e.g., Arkins, ASilane Coupling Agent Chemistry,” Petrarch Systems Register and Review, Eds. Anderson et al. (1987) and U.S. Pat. No. 6,258,454.

Any given substrate may carry one, two, four or more arrays disposed on a surface of the substrate. Depending upon the use, any or all of the arrays may be the same or different from one another and each may contain multiple spots or features. For example, a plurality of arrays may be stably associated with one substrate, where the arrays are spatially separated from some or all of the other arrays associated with the substrate.

FIGS. 2A-2C show an exemplary embodiment of the elements of a backing element/microarray assembly structure 160, wherein at least one element thereof (at least one of the backing element substrate, gasket structure and microarray assembly (e.g., microarray substrate) has been treated in accordance with the subject invention. FIGS. 2A-2C are described with reference to a treated backing element substrate and gasket for exemplary purposes only and is in no way intended to limit the invention as it will be apparent that other members of a microarray structure may be treated, in addition to or in instead of the backing element substrate and gasket and/or only one of the backing element substrate and gasket may be treated- or non at all (e.g., the microarray assembly may be treated). As shown in FIGS. 2A-2C, to provide a sealed assay chamber 60 about one or more arrays of an array assembly using a treated backing element substrate, treated gasket element and a microarray assembly (i.e., a microarray substrate with one or more arrays), a treated backing element 43 having at least one gasket 40 positioned on a surface 42 of the backing element substrate 41 is positioned in opposition to a microarray assembly 53 having a microarray substrate 51 with one or more arrays 50 (not shown) on a surface 52 of substrate 51 such that gasket 40 of backing element 43 is facing and is in direct opposition to the surface 52 of the microarray substrate 51 that has arrays 50 thereon, as shown in FIG. 2A. As noted above, the gasket may be associated with the microarray substrate or may be a separable component from both substrates 41 and 51. The treated backing element 43 and microarray 53 are brought into sufficiently close proximity to “sandwich” the gasket between the two, as shown in FIG. 2B and FIG. 2C, where FIG. 2C shows a cross sectional view of the operatively positioned treated backing element and microarray of FIG. 2B. In this manner, a backing element/microarray assembly structure 160 is provided that forms a sealed array assay chamber 60 about the one or more arrays 50 by surface 52 of microarray 53, surface 42 of backing element 43 and the walls of the gasket 40.

As described above, the array assay chamber formed with a treated backing element and a microarray may be employed in a variety of different applications, where such applications are generally analyte detection applications in which the presence of a particular analyte in a given sample is detected at least qualitatively, if not quantitatively. Protocols for carrying out such assays are well known to those of skill in the art and need not be described in great detail here. Generally, the sample suspected of comprising the analyte of interest is contacted with an array under conditions sufficient for the analyte to bind to its respective binding pair member that is present on the array. Thus, if the analyte of interest is present in the sample, it binds to the array at the site of its complementary binding member and a complex is formed on the array surface. The presence of this binding complex on the array surface is then detected, e.g., through use of a signal production system, e.g., an isotopic or fluorescent label present on the analyte, etc. The presence of the analyte in the sample is then deduced from the detection of binding complexes on the substrate surface.

Specific analyte detection applications of interest include hybridization assays in which the nucleic acid arrays of the invention are employed. In these assays, a sample of target nucleic acids is first prepared, where preparation may include labeling of the target nucleic acids with a label, e.g., a member of signal producing system. Following sample preparation, the sample is contacted with the array under hybridization conditions, whereby complexes are formed between target nucleic acids that are complementary to probe sequences attached to the array surface. The presence of hybridized complexes is then detected. Specific hybridization assays of interest which may be practiced using the arrays include: gene discovery assays, differential gene expression analysis assays; nucleic acid sequencing assays, and the like. Patents and patent applications describing methods of using arrays in various applications include: U.S. Pat. Nos. 5,143,854; 5,288,644; 5,324,633; 5,432,049; 5,470,710; 5,492,806; 5,503,980; 5,510,270; 5,525,464; 5,547,839; 5,580,732; 5,661,028; 5,800,992; the disclosures of which are herein incorporated by reference.

Where the arrays are arrays of polypeptide binding agents, e.g., protein arrays, specific applications of interest include analyte detection/proteomics applications, including those described in: U.S. Pat. Nos. 4,591,570; 5,171,695; 5,436,170; 5,486,452; 5,532,128; and 6,197,599; the disclosures of which are herein incorporated by reference; as well as published PCT application Nos. WO 99/39210; WO 00/04832; WO 00/04389; WO 00/04390; WO 00/54046; WO 00/63701; WO 01/14425; and WO 01/40803; the disclosures of the United States priority documents of which are herein incorporated by reference.

In certain embodiments, the methods include a step of transmitting data from at least one of the detecting and deriving steps, as described above, to a remote location. By “remote location” is meant a location other than the location at which the array is present and hybridization occur. For example, a remote location could be another location (e.g., office, lab, etc.) in the same city, another location in a different city, another location in a different state, another location in a different country, etc. As such, when one item is indicated as being “remote” from another, what is meant is that the two items are at least in different buildings, and may be at least one mile, ten miles, or at least one hundred miles apart. “Communicating” information means transmitting the data representing that information as electrical signals over a suitable communication channel (for example, a private or public network). “Forwarding” an item refers to any means of getting that item from one location to the next, whether by physically transporting that item or otherwise (where that is possible) and includes, at least in the case of data, physically transporting a medium carrying the data or communicating the data. The data may be transmitted to the remote location for further evaluation and/or use. Any convenient telecommunications means may be employed for transmitting the data, e.g., facsimile, modem, Internet, etc.

Accordingly, in use a backing element may be mated with an array such that at least one gasket is positioned therebetween to provide an array assay chamber in which an array assay may be performed, wherein the array will typically be exposed to a sample (for example, a fluorescently labeled analyte, e.g., protein containing sample) and the array then read. At least one of the microarray substrate, backing element substrate and gasket is treated in accordance with the subject invention. Reading of the array may be accomplished by illuminating the array and reading the location and intensity of resulting fluorescence at each feature of the array to detect any binding complexes on the surface of the array. For example, a scanner may be used for this purpose which is similar to the AGILENT MICROARRAY SCANNER available from Agilent Technologies, Palo Alto, Calif. Other suitable apparatus and methods are described in U.S. Pat. Nos. 5,091,652; 5,260,578; 5,296,700; 5,324,633; 5,585,639; 5,760,951; 5,763,870; 6,084,991; 6,222,664; 6,284,465; 6,371,370 6,320,196 and 6,355,934; the disclosures of which are herein incorporated by reference. However, arrays may be read by any other method or apparatus than the foregoing, with other reading methods including other optical techniques (for example, detecting chemiluminescent or electroluminescent labels) or electrical techniques (where each feature is provided with an electrode to detect hybridization at that feature in a manner disclosed in U.S. Pat. No. 6,221,583 and elsewhere). Results from the reading may be raw results (such as fluorescence intensity readings for each feature in one or more color channels) or may be processed results such as obtained by rejecting a reading for a feature which is below a predetermined threshold and/or forming conclusions based on the pattern read from the array (such as whether or not a particular target sequence may have been present in the sample). The results of the reading (processed or not) may be forwarded (such as by communication) to a remote location if desired, and received there for further use (such as further processing).

As such, in using the subject backing elements in an array assay, a sample suspected of including an analyte of interest, i.e., a target molecule, is first contacted with a first substrate, e.g., a treated backing element, to produce a substrate supported sample, e.g., a backing element supported sample (in certain embodiments the sample may be contacted with the microarray). For example, a sample may be contacted with a treated backing element by depositing an amount of sample in the one or more fluid retaining structures (treated or not) positioned on a surface of the treated backing element to confine a certain amount of sample to a certain fluid retaining structure. The sample may be contacted with the backing element (i.e., deposited into a fluid retaining structure) using any suitable protocol, where in many embodiments a deposition type protocol is employed, e.g., by pipette or other fluid dispenser. The resultant treated backing element supported sample may then be contacted with an array, following which step the remainder of the assay may be carried out, as described above. Following sample deposition into the one or more fluid retaining structures of the backing element, the resultant backing element supported sample may be incubated as desired prior to contact with a microarray or may be immediately contacted with an array.

To contact a treated backing element supported sample with the microarray (treated or not), the microarray and treated backing element supported sample may be brought together in a manner sufficient so that the sample contacts the ligands of the microarray (see, e.g., FIGS. 2A-2C). As such, the microarray may be placed on top of the treated backing element supported sample, and where desired the resultant structure turned upside down to ensure that the sample contacts the entire array surface. Following contact of the microarray and the sample, the resultant sample contacted microarray structure (i.e., the structure provided by the microarray and treated backing element) is then maintained under conditions sufficient, and for a sufficient period of time, for any binding complexes between members of specific binding pairs to occur. Where desired, the sample may be agitated or mixed (e.g., using bubble mixing where a bubble has been provided in the array assay chamber) to ensure contact of the sample with the array. In the case of hybridization assays, the treated backing element supported sample is typically contacted with the microarray under stringent hybridization conditions, whereby complexes are formed between target nucleic acids that are complementary to probe sequences attached to the array surface, i.e., duplex nucleic acids are formed on the surface of the substrate by the interaction of the probe nucleic acid and its complement target nucleic acid present in the sample.

The term “stringent conditions” refers to conditions under which a probe will hybridize preferentially to its target subsequence, and to a lesser extent to, or not at all to, other sequences. Put another way, the term “stringent hybridization conditions” as used herein refers to conditions that are compatible to produce duplexes on an array surface between complementary binding members, e.g., between probes and complementary targets in a sample, e.g., duplexes of nucleic acid probes, such as DNA probes, and their corresponding nucleic acid targets that are present in the sample, e.g., their corresponding mRNA analytes present in the sample. A “stringent hybridization” and “stringent hybridization wash conditions” in the context of nucleic acid hybridization (e.g., as in array, Southern or Northern hybridizations) are sequence dependent, and are different under different environmental parameters. Stringent hybridization conditions that can be used to identify nucleic acids within the scope of the invention can include, e.g., hybridization in a buffer comprising 50% formamide, 5×SSC, and 1% SDS at 42° C., or hybridization in a buffer comprising 5×SSC and 1% SDS at 65° C., both with a wash of 0.2×SSC and 0.1% SDS at 65° C. Exemplary stringent hybridization conditions can also include a hybridization in a buffer of 40% formamide, 1 M NaCl, and 1% SDS at 37° C., and a wash in 1×SSC at 45° C. Alternatively, hybridization to filter-bound DNA, or DNA bound to an other analogous susbstrate, in 0.5 M NaHPO₄, 7% sodium dodecyl sulfate (SDS), 1 mnM EDTA at 65° C., and washing in 0.1×SSC/0.1% SDS at 68° C. can be employed. Yet additional stringent hybridization conditions include hybridization at 60° C. or higher and 3×SSC (450 mM sodium chloride/45 mM sodium citrate) or incubation at 42° C. in a solution containing 30% formamide, 1M NaCl, 0.5% sodium sarcosine, 50 mM MES, pH 6.5. Those of ordinary skill will readily recognize that alternative but comparable hybridization and wash conditions can be utilized to provide conditions of similar stringency.

In certain embodiments, the stringency of the wash conditions that set forth the conditions which determine whether a nucleic acid is specifically hybridized to a probe. Wash conditions used to identify nucleic acids may include, e.g.: a salt concentration of about 0.02 molar at pH 7 and a temperature of at least about 50° C. or about 55° C. to about 60° C.; or, a salt concentration of about 0.15 M NaCl at 72° C. for about 15 minutes; or, a salt concentration of about 0.2×SSC at a temperature of at least about 50° C. or about 55° C. to about 60° C. for about 15 to about 20 minutes; or, the hybridization complex is washed twice with a solution with a salt concentration of about 2×SSC containing 0.1% SDS at room temperature for 15 minutes and then washed twice by 0.1×SSC containing 0.1% SDS at 68° C. for 15 minutes; or, equivalent conditions. Stringent conditions for washing can also be, e.g., 0.2×SSC/0.1% SDS at 42° C. In instances wherein the nucleic acid molecules are deoxyoligonucleotides (“oligos”), stringent conditions can include washing in 6×SSC/0.05% sodium pyrophosphate at 37° C. (for 14-base oligos), 48° C. (for 17-base oligos), 55° C. (for 20-base oligos), and 60° C. (for 23-base oligos). See Sambrook, Ausubel, or Tijssen (cited below) for detailed descriptions of equivalent hybridization and wash conditions and for reagents and buffers, e.g., SSC buffers and equivalent reagents and conditions.

Stringent hybridization conditions are hybridization conditions that are at least as stringent as the above representative conditions, where conditions are considered to be at least as stringent if they are at least about 80% as stringent, typically at least about 90% as stringent as the above specific stringent conditions. Other stringent hybridization conditions are known in the art and may also be employed, as appropriate.

Once the incubation step is complete, the backing element and microarray are separated and the microarray is typically washed at least one time to remove any unbound and non-specifically bound sample from the microarray substrate, generally at least two wash cycles are used. Washing agents used in array assays are known in the art and, of course, may vary depending on the particular binding pair used in the particular assay. For example, in those embodiments employing nucleic acid hybridization, washing agents of interest include, but are not limited to, salt solutions such as sodium, sodium phosphate and sodium, sodium chloride and the like as is known in the art, at different concentrations and may include some surfactant as well. For example, an array may be washed in, first, 6×SSC with 0.005% Triton X102 at about 60° C. or at about 20° C. and then 0.1×SSC at about 20° C. or at about at about 4°.

Following the washing procedure, as described above, the microarray may then be interrogated or read so that the presence of the binding complexes may be detected, e.g., through use of a signal production system, e.g. an isotopic or fluorescent label present on the analyte, etc., as described above. The presence of the analyte in the sample may then be deduced from the detection of binding complexes on the microarray substrate surface.

Systems

Also provided by the subject invention are systems that include a backing element/microarray assembly structure wherein at least one member has been treated in accordance with the subject invention. Accordingly, embodiments of the subject systems may include a treated backing element substrate and/or treated gasket and/or treated microarray assembly having a microarray substrate and at least one microarray on a surface of the substrate, as described above. The microarray assembly and backing element substrate are dimensioned to be operatively joined or fit together with a gasket therebetween. In this manner, at least one gasket structure is provided about the at least one array and in certain embodiments a plurality of gasket structures are provided wherein each array feature is bounded by a respective gasket structure. The system may also include a sample suspected of including an analyte of interest, where such sample may be used with the backing element/microarray assembly structure in an array assay protocol such as an analyte detection protocol. In certain embodiments, the subject systems may further include reagents employed in array based assay protocols, including sample preparation reagents, e.g., labeling reagents, etc; washing fluids; etc. Embodiments may also include suitable containers for performing treatments in accordance with the subject invention.

Kits

Finally, kits are also provided. Embodiments of the subject kits may at least include one or more members of a backing element/microarray assembly structure wherein one or more members have been treated in accordance with the subject invention. For example, embodiments may include backing element substrates having at least one gasket thereon wherein the substarte and/or gasket has been treated in accordance with the subject invention, as described above. The subject kits may also include one or more microarray assemblies (treated or not). If not fixedly attached to a substrate, one or more separate gaskets may also be provided. The kits may also include a device for holding a backing element substrate and microarray assembly in a fixed position relative to each other with a gasket therebetween to perform an array assay such as an array assay device that provides a compression force to at least one member of a backing element/microarray assembly structure. The kits may further include one or more additional components necessary for carrying out an analyte detection assay, such as sample preparation reagents, buffers, labels, and the like. As such, the kits may include one or more containers such as vials or bottles, with each container containing a separate component for the assay, and reagents for carrying out an array assay such as a nucleic acid hybridization assay or the like. The kits may also include a denaturation reagent for denaturing the analyte, buffers such as hybridization buffers, wash mediums, enzyme substrates, reagents for generating a labeled target sample such as a labeled target nucleic acid sample, negative and positive controls.

Certain embodiments may include one or more backing element substrates that may include one or a plurality of gasket structures thereon wherein the substrate and/or gaskets are treated in accordance with the subject invention. In certain embodiments, a plurality of treated backing element substrates may be provided, where some or all may be the same or some or all may be different in one or more respects, e.g., differ in the number of gasket structures present, the pattern of the one or more gasket structures, the size of the one or more gasket structures, the shape of the one or more gasket structures, the material of the one or more gasket structures, the volume of the one or more gasket structures, etc., and/or differ in the size, shape, material, etc., of the treated backing element substrate, etc., such that a variety of different treated backing elements may be provided in a kit for a variety of different applications and/or to fit with a variety of different microarrays.

In addition to the above components, the subject kits may also include written instructions for using the components of the kit in an array assay. The instructions may be printed on a substrate, such as paper or plastic, etc. As such, the instructions may be present in the kits as a package insert, in the labeling of the container of the kit or components thereof (i.e., associated with the packaging or sub-packaging) etc. In other embodiments, the instructions are present as an electronic storage data file present on a suitable computer readable storage medium, e.g., CD-ROM, diskette, etc. In yet other embodiments, the actual instructions are not present in the kit, but means for obtaining the instructions from a remote source, e.g. via the Internet, are provided. An example of this embodiment is a kit that includes a web address where the instructions can be viewed and/or from which the instructions can be downloaded. As with the instructions, this means for obtaining the instructions is recorded on a suitable substrate.

In many embodiments of the subject kits, the components of the kit are packaged in a kit containment element to make a single, easily handled unit, where the kit containment element, e.g., box or analogous structure, may or may not be an airtight container, e.g., to further preserve the one or more treated backing elements and one or more microarrays and reagents, if present, until use.

### EXPERIMENTAL

The following example is put forth so as to provide those of ordinary skill in the art with a complete disclosure and description of how to make and use the present invention, and are not intended to limit the scope of what the inventors regard as their invention. Efforts have been made to ensure accuracy with respect to numbers used (e.g. amounts, temperature, etc.) but some experimental errors and deviations should be accounted for. Unless indicated otherwise, parts are parts by weight, molecular weight is weight average molecular weight, temperature is in degrees Centigrade, and pressure is at or near atmospheric.

### Experiment 1

Backing element substrates having gaskets thereon were prepared as test vehicles with extra fluid-retaining gasket material and were processed as follows:
1. A first set of backing elements was cured for 10 minutes; a second set was cured for 3 hours; a third set was cured for 22 hours.
2. Gaskets from each of the three groups were exposed to three solvents: toluene, isopropyl alcohol, and 3M HFE-7200 (ethyl nonafluoroisobutyl ether/ethyl nonafluorobutyl ether).
3. Exposure times were 30, 60, 120, 240, 480, 640 minutes
4. After each exposure to solvent, the backing elements were weighed, yielding the amount of material removed by the solvents.
   Results:

Weight loss (indicative of undesirable material (low melting point monomers as described above (D4-D20 series linear or cyclic siloxanes)) that the solvents were effective at removing unwanted material from a gasket. The results also showed that weight loss (i.e., the amount of material removed) depended on the solvent type, time of solvent exposure and gasket cure time. These parameters yielded the following results for gasket weight loss in this experiment:
(1) solvent (toluene>isopropyl alcohol>HFE 7200);
(2) time of exposure (640>480>240, etc.); and
(3) time of cure (10 minutes>180 minutes>22 hours).

### Experiment 2

Backing element substrates having gaskets thereon were exposed to different solvents to evaluate each solvent's ability to remove residue-causing components from the silicone gasket material. The backing elements were processed as follows:
1. Each backing element was washed in a detergent solution.
2. Each backing element was soaked in one of the following solvents for 30 minutes:
   Toluene
   N,N Dimethylformamide
   Tetrahydrofuran
   Acetone
   Methylene Chloride
   Dichloromethane
   2-Propanol
   Hexane
   1-Butanol
   RBS (Medline Scientific Limited)
   LPS PreSolve (limonene+naphtha) (LPS Laboratories)
   LPS Electro Contact Cleaner
   LPS Precision Clean
   LPS HDX degreaser
   DeContam (ESPI)
   3M FC-40 & FC-77
   3M HFC-7100

One control set with no solvent soak.
3) The backing elements were dried at 50° C. in vacuum (27 mm Hg)
4) The solvent treated backing elements were then used with a microarray in a microarray hybridization procedure and then the hybridized microarray with an Agilent Technologies Microarray Scanner and viewed for residue.
   Results:

The control set of backing elements had residue. Some of the solvent-treated backings showed some residue (backing elements treated with: N,N Dimethylformamide, 2-propanol, DeContam, LPS HDXS, LPS Electro Contact Cleaner, Dichloromethane and some others). The remaining solvent-treated backing elements did not have any residue.

### Experiment 3

Two types of backing elements having different shapes of cured silicone rubber gaskets on 1″×3″ glass were processed as follows:
1) Each backing element was exposed to an oxygen plasma to improve their hydrophilicity.
2) Each backing element was then soaked for 30 minutes in toluene at room temperature, with occasional agitation.
3) Each was drained and soaked another 30 minutes in fresh toluene.
4) Each was drained and lightly misted with toluene to wash down any remaining contaminated solvent.
5) Each was blown dry with a nitrogen gun.
6) Each was used with a DNA microarray in a DNA microarray hybridization procedure.
   Results:

Hydrophilicity was one of the parameters evaluated. The results showed that dewetting occurrences during the hybridization went from 80% to 5%. The impact on the data went form strong significance to no significance. Residue was also evaluated. The results showed that residue events went from 1-10 detected events to zero.

It is evident from the above results and discussion that the above-described invention provides simple, low cost, effective and easy to use methods to treat at least one member of a backing element/microarray assembly structure. As such, the subject invention represents a significant contribution to the art.

All publications and patents cited in this specification are herein incorporated by reference as if each individual publication or patent were specifically and individually indicated to be incorporated by reference. The citation of any publication is for its disclosure prior to the filing date and should not be construed as an admission that the present invention is not entitled to antedate such publication by virtue of prior invention.

While the present invention has been described with reference to the specific embodiments thereof, it should be understood by those skilled in the art that various changes may be made and equivalents may be substituted without departing from the true spirit and scope of the invention. In addition, many modifications may be made to adapt a particular situation, material, composition of matter, process, process step or steps, to the objective, spirit and scope of the present invention. All such modifications are intended to be within the scope of the claims appended hereto.

1. A method for treating at least one member of a backing element/microarray assembly structure, said method comprising at least one of: (1) depositing a component on said at least one member, (2) extracting a component from said at least one member, (3) surface modifying said at least one member, to treat said at least one member of a backing element/microarray assembly structure.

2. The method of claim 1, wherein said method comprises depositing a component on said at least one member of a backing element/microarray assembly structure and said depositing comprises performing a SiO₂ deposition protocol.

3. The method of claim 1, wherein said method comprises extracting a component from said at least one member of a backing element/microarray assembly structure.

4. The method of claim 3, wherein said method comprises contacting said at least one member of a backing element/microarray assembly structure with at least one of a liquid phase and a vapor phase.

5. The method of claim 4, wherein said component comprises moieties that may adversely affect an array or its reading.

6. The method of claim 5, wherein said moieties are removed at least from a gasket of said backing element/microarray assembly structure.

7. The method of claim 5, wherein said moieties comprise low-melting point monomers or truncated polymers.

8. The method of claim 7, wherein said low-melting point monomers are D4-D20 series linear or cyclic siloxanes.

9. The method of claim 4, wherein said extraction comprises contacting said at least one member of a backing element/microarray assembly structure with at least one solvent to extract said component.

10. The method of claim 9, wherein said at least one solvent is an aqueous solvent.

11. The method of claim 10, wherein said at least one solvent is an organic solvent.

12. The method of claim 11, wherein said organic solvent is a polar organic solvent.

13. The method of claim 12, wherein said polar organic solvent is chosen from alcohols, ketones, trialkyl amines, tributyl amines and cyclic solvents.

14. The method of claim 11, wherein said organic solvent is a non-polar organic solvent.

15. The method of claim 14, wherein said non-polar organic solvent is chosen from aliphatic hydrocarbons, aromatic hydrocarbons, ethers and glymes.

16. The method of claim 1, wherein said method comprises surface modifying said at least one member of a backing element/microarray assembly structure.

17. The method of claim 16, wherein said surface modification comprises contacting said at least one member of a backing element/microarray assembly structure with a plasma.

18. The method of claim 17, wherein said plasma is produced from nitrogen, air, argon, oxygen, nitrous oxide, helium, water vapor, carbon dioxide, methane, and combinations thereof.

19. The method of claim 16, wherein said surface modification comprises contacting said at least one member of a backing element/microarray assembly structure with a gas/air mixture.

20. The method of claim 16, wherein said surface modification comprises contacting said at least one member of a backing element/microarray assembly structure with a plurality of beads.

21. The method of claim 16, wherein said surface modification comprises contacting said at least one member of a backing element/microarray assembly structure with at least one form of radiant energy.

22. The method of claim 16, wherein said surface modification comprises exposing said at least one member of a backing element/microarray assembly structure to UV/O₂.

23. The method of claim 16, wherein said surface modification comprises bombarding said at least one member of a backing element/microarray assembly structure with electrons.

24. The method of claim 16, wherein said surface modification comprises contacting said at least one member of a backing element/microarray assembly structure with at least one reactive gas.

25. The method of claim 16, wherein said surface modification comprises:
(a) introducing soluble particulates to uncured gasket material,
(b) curing said gasket material, and
(c) solubalizing said soluble particulates to provide said textured gasket surface.

26. The method of claim 1, wherein said treatment comprises oxidizing at least one surface of said at least one member of a backing element/microarray assembly structure.

27. The method of claim 1, wherein said treatment comprises increasing the hydrophilicity of said at least one member of a backing element/microarray assembly structure.

28. The method of claim 1, wherein said treatment provides a seal about at least elastomeric gasket of said backing element/microarray assembly structure.

29. The method of claim 1, wherein said treatment comprises sequentially contacting said at least one member of a backing element/microarray assembly structure with at least two of: plasma, UV/O₂ and a solvent.

30. The method of claim 1, wherein said contacted member is a substrate.

31. The method of claim 30, wherein said substrate is a backing element substrate.

32. The method of claim 30, wherein said substrate is a microarray substrate.

33. The method of claim 1, wherein said contacted member is a gasket.

34. A treated backing element comprising a substrate with a surface bounded by a polymeric gasket, said backing element comprising at least one of: (1) an area comprising a deposited component, (2) an area wherein at least one component has been extracted, and (3) a surface modified area.

35. A method of detecting the presence of an analyte in a sample, said method comprising:
(a) contacting a sample suspected of comprising said analyte with a backing element/microarray assembly structure treated according to claim 1 under conditions sufficient for binding of said analyte to said ligand on said microarray substrate to occur, wherein said microarray assembly comprises a ligand that specifically binds to said analyte of; and
(c) detecting the presence of binding complexes on the surface of said microarray assembly to detect the presence of said analyte in said sample.

36. A method comprising transmitting data representing a result obtained from a method of claim 35 from a first location to a second location.

37. A method comprising receiving a transmitted result of a reading of a microarray obtained according to the method claim 35.

38. A system comprising:
(a) a sample suspected of comprising an analyte; and
(b) a backing element/microarray assembly structure treated according to claim 1.

39. A kit comprising:
(a) at least one member of a backing element/microarray assembly structure treated according to claim 1; and
(b) instructions for using said treated member in an array assay.
